(19) United States
(12) Patent Application Publication
(10) Pub. No.: US 2026/0096267 A1
(43) Pub. Date: Apr. 2, 2026

(54) DISPLAY APPARATUS AND ELECTRONIC DEVICE

(71) Applicant: Samsung Display Co., Ltd., Yongin-si (KR)

(72) Inventors: Seungjun Lee, Yongin-si (KR); Seongwon Kim, Yongin-si (KR); Junsu Park, Yongin-si (KR); Youngseok Seo, Yongin-si (KR); Mankyu Jo, Yongin-si (KR)

(21) Appl. No.: 19/304,133

(22) Filed: Aug. 19, 2025

(30) Foreign Application Priority Data
Oct. 2, 2024 (KR) 10-2024-0134221

(51) Int. Cl. H10H 29/49; H10K 59/131

(52) U.S. Cl. CPC H10H 29/49; H10K 59/131

(57) ABSTRACT

A display apparatus including a display area and a non-display area includes a plurality of 11^{th} island portions and a plurality of 12^{th} island portions in the display area and alternately arranged to be spaced from each other along a first direction and a second direction intersecting the first direction, and a first connection wiring extending in the first direction overlapping the plurality of 11^{th} island portions and the plurality of 12^{th} island portions arranged along the first direction in a plan view, wherein the first connection wiring includes a 1-1 connection wiring electrically connected to each of the plurality of 11^{th} island portions, and a 1-2 connection wiring spaced from the 1-1 connection wiring and electrically connected to each of the plurality of 12^{th} island portions.

### CROSS-REFERENCE TO RELATED APPLICATION

This application claims priority to and the benefit of Korean Patent Application No. 10-2024-0134221, filed on Oct. 2, 2024, in the Korean Intellectual Property Office, the entire disclosure of which is incorporated by reference herein.

### BACKGROUND

### 1. Field

One or more embodiments relate to a display apparatus, for example, a flexible display apparatus.

### 2. Description of the Related Art

As display apparatuses that visually display electrical signals have been developed, various display apparatuses having excellent characteristics such as a thin design, light weight, and low power consumption have been introduced. For example, flexible display apparatuses that may be folded and/or rolled up have been introduced. Recently, research on and development of display apparatuses having various structures, such as stretchable display apparatuses that may be changed into various forms, have been actively conducted.

### SUMMARY

One or more embodiments include a display apparatus, for example, a flexible display apparatus.

Additional aspects and features of embodiments of the present disclosure will be set forth in part in the description which follows and, in part, will be apparent from the description, or may be learned by practice of embodiments of the present disclosure.

According to one or more embodiments, a display apparatus including a display area and a non-display area includes a plurality of 11^{th} island portions and a plurality of 12^{th} island portions in the display area and alternately arranged to be spaced from each other along a first direction and a second direction intersecting the first direction, and a first connection wiring extending in the first direction overlapping the plurality of 11^{th} island portions and the plurality of 12^{th} island portions arranged along the first direction in a plan view, wherein the first connection wiring includes a 1-1 connection wiring electrically connected to each of the plurality of 11^{th} island portions, and a 1-2 connection wiring spaced from the 1-1 connection wiring and electrically connected to each of the plurality of 12^{th} island portions.

In a cross-sectional view, the 1-1 connection wiring may be spaced from a transistor of a 12^{th} island portion from among the plurality of 12^{th} island portions, and the 1-2 connection wiring may be spaced from a transistor of a 11^{th} island portion from among the plurality of 11^{th} island portions.

The 1-1 connection wiring may include a 1-11 connection wiring, and a 1-12 connection wiring on a different layer from the 1-11 connection wiring.

Each of the 1-11 connection wiring and the 1-12 connection wiring may have a curved or bent shape, wherein, in a plan view, the 1-11 connection wiring and the 1-12 connection wiring cross each other at a first position and are spaced from each other at a second position different from the first position.

The display apparatus may further include a second connection wiring extending in the second direction overlapping the plurality of 11^{th} island portions and the plurality of 12^{th} island portions arranged along the second direction in a plan view, wherein the second connection wiring includes a 2-1 connection wiring electrically connected to each of the plurality of 11^{th} island portions, and a 2-2 connection wiring spaced from the 1-1 connection wiring and electrically connected to each of the plurality of 12^{th} island portions.

The display apparatus may further include a plurality of first connection wirings and a plurality of second connection wirings, wherein the plurality of first connection wirings are spaced from each other along the second direction, and the plurality of second connection wirings may be spaced from each other along the first direction.

At least one of the first connection wiring or the second connection wiring may include at least one of a voltage line or a signal line.

The display apparatus may further include a first power supply wiring including a 1-1 power supply wiring configured to supply a 1-1 power supply voltage to the 1-1 connection wiring and a 1-2 power supply wiring configured to supply a 1-2 power supply voltage to the 1-2 connection wiring, and a second power supply wiring including a 2-1 power supply wiring configured to supply a 2-1 power supply voltage to the 2-1 connection wiring and a 2-2 power supply wiring configured to supply a 2-2 power supply voltage to the 2-2 connection wiring.

In a plan view, the 1-1 power supply wiring may overlap the 1-2 power supply wiring, and the 2-1 power supply wiring may overlap the 2-2 power supply wiring.

The 1-1 power supply wiring, the 2-1 power supply wiring, the 1-2 power supply wiring, and the 2-2 power supply wiring may be around the display area.

According to one or more embodiments, an electronic device includes a display apparatus having a display area and a non-display area, the display apparatus including a plurality of 11^{th} island portions spaced from each other along a first direction and a second direction intersecting the first direction, a plurality of 12^{th} island portions spaced from each other along the first direction and the second direction, and a first connection wiring extending in the first direction overlapping the plurality of 11^{th} island portions and the plurality of 12^{th} island portions arranged along the first direction in a plan view, wherein the first connection wiring includes a 1-1 connection wiring electrically connected to each of the plurality of 11^{th} island portions, and a 1-2 connection wiring spaced from the 1-1 connection wiring and electrically connected to each of the plurality of 12^{th} island portions.

The plurality of 11^{th} island portions and the plurality of 12^{th} island portions may be arranged in a lattice shape.

The plurality of 11^{th} island portions may be located at a position of (2a-1)^{th} row (2b-1)^{th} column or a position of (2c)^{th} row (2d)^{th} column, (where a, b, c, and d are positive numbers greater than 0).

The plurality of 12^{th} island portions may be located at a position of (2a-1)^{th} row (2d)^{th} column or a position of (2c)^{th} row (2b-1)^{th} column, (where a, b, c, and d are positive numbers greater than 0).

In a cross-sectional view, the 1-1 connection wiring may be spaced from a transistor of a 12^{th} island portion from among the plurality of 12^{th} island portions, and the 1-2 connection wiring may be spaced from a transistor of a 11^{th} island portion from among the plurality of 11^{th} island portions.

The 1-1 connection wiring may include a 1-11 connection wiring, and a 1-12 connection wiring on a different layer from the 1-11 connection wiring.

Each of the 1-11 connection wiring and the 1-12 connection wiring may have a curved or bent shape, wherein, in a plan view, the 1-11 connection wiring and the 1-12 connection wiring cross each other at a first position and are spaced from each other at a second position different from the first position.

The display apparatus may further include a second connection wiring extending in the second direction overlapping the plurality of 11^{th} island portions and the plurality of 12^{th} island portions arranged along the second direction in a plan view, wherein the second connection wiring includes a 2-1 connection wiring electrically connected to each of the plurality of 11^{th} island portions, and a 2-2 connection wiring spaced from the 1-1 connection wiring and electrically connected to each of the plurality of 12^{th} island portions.

The display apparatus may further include a first power supply wiring including a 1-1 power supply wiring configured to supply a 1-1 power supply voltage to the 1-1 connection wiring and a 1-2 power supply wiring configured to supply a 1-2 power supply voltage to the 1-2 connection wiring, and a second power supply wiring including a 2-1 power supply wiring configured to supply a 2-1 power supply voltage to the 2-1 connection wiring and a 2-2 power supply wiring configured to supply a 2-2 power supply voltage to the 2-2 connection wiring.

In a plan view, the 1-1 power supply wiring may overlap the 1-2 power supply wiring, and the 2-1 power supply wiring may overlap the 2-2 power supply wiring.

Other aspects and features, of the present disclosure will become more apparent from the drawings, the claims, and the detailed description.

### BRIEF DESCRIPTION OF THE DRAWINGS

The above and other aspects and features of certain embodiments will be more apparent from the following description taken in conjunction with the accompanying drawings, in which:

FIG. 1 is a perspective view schematically illustrating a display apparatus, according to one or more embodiments;

FIGS. 2A and 2B are perspective views illustrating a state where the display apparatus of FIG. 1 is stretched in a first direction;

FIG. 2C is a perspective view illustrating a state where the display apparatus of FIG. 1 is stretched in a second direction;

FIG. 2D is a perspective view illustrating a state where the display apparatus of FIG. 1 is stretched in the first direction and the second direction;

FIG. 2E is a perspective view illustrating a state where the display apparatus of FIG. 1 is stretched in a third direction;

FIG. 3 is a plan view schematically illustrating a part of a display apparatus, according to one or more embodiments;

FIG. 4A is a plan view illustrating a part of a display apparatus, according to one or more embodiments;

FIG. 4B is a plan view illustrating a part of a display apparatus, according to one or more embodiments;

FIG. 4C is a plan view illustrating a display apparatus, according to one or more embodiments;

FIG. 5 is a cross-sectional view schematically illustrating a first island portion and a first bridge portion disposed in a display area of a display apparatus, according to one or more embodiments;

FIGS. 6A-6C are equivalent circuit diagrams illustrating a sub-pixel of a display apparatus, according to one or more embodiments;

FIG. 7A is a cross-sectional view schematically illustrating a light-emitting element of a display apparatus, according to one or more embodiments;

FIG. 7B is a cross-sectional view schematically illustrating a light-emitting element of a display apparatus, according to one or more embodiments;

FIG. 8 is an enlarged plan view illustrating a first island portion and a first bridge portion of a display apparatus, according to one or more embodiments;

FIG. 9 is a cross-sectional view schematically illustrating a display apparatus, according to one or more embodiments;

FIG. 10A is a plan view schematically illustrating a part of a display apparatus, according to one or more embodiments;

FIG. 10B is a plan view schematically illustrating a part of a display apparatus, according to one or more embodiments;

FIG. 11 is a cross-sectional view schematically illustrating a display apparatus, according to one or more embodiments;

FIG. 12A is a plan view schematically illustrating a part of a display apparatus, according to one or more embodiments;

FIG. 12B is a plan view schematically illustrating a part of a display apparatus, according to one or more embodiments;

FIGS. 13A-13C are plan views schematically illustrating a part of a display apparatus, according to one or more embodiments;

FIGS. 14A-14C are plan views schematically illustrating a part of a display apparatus, according to one or more embodiments;

FIGS. 15A-15C are plan views schematically illustrating a part of the display apparatus, according to one or more embodiments; and

FIGS. 16A-16G are perspective views schematically illustrating embodiments of an electronic device including a display apparatus, according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, embodiments are merely described below, by referring to the figures, to explain aspects and features of the present disclosure. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

As the present disclosure allows for various changes and numerous embodiments, certain embodiments will be illustrated in the drawings and described in the detailed description. Effects, aspects, and features of the present disclosure, and methods for achieving them will be clarified with reference to embodiments described below in detail with reference to the drawings. However, the present disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including” and “having” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the present disclosure is not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

When a certain embodiment may be implemented differently, a specific process order may be different from the described order. For example, two consecutively described processes may be performed substantially at the same time or may be performed in an order opposite to the described order.

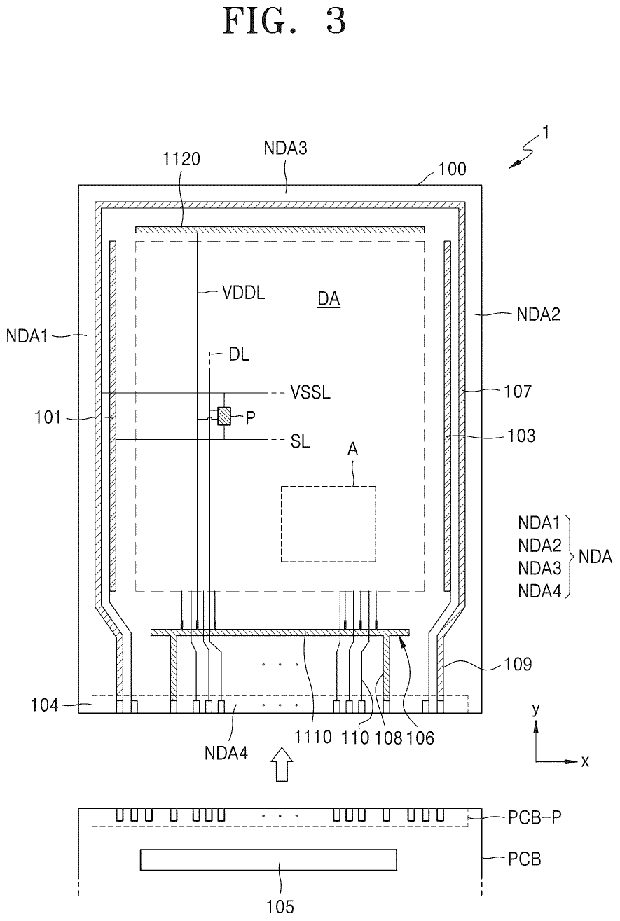

In the specification, a “plan view” refers to a two-dimensional view seen in a direction perpendicular to a substrate 100 (see FIG. 3). That is, “A and B spaced (e.g., spaced apart) from each other in a plan view” means “A and B spaced (e.g., spaced apart) from each other when viewed in a direction perpendicular to the substrate 100 (see FIG. 3).”

In the specification, a “cross-sectional view” refers to a two-dimensional view cut in a direction perpendicular to the substrate 100 (see FIG. 3). That is, “A and B spaced (e.g., spaced apart) from each other in a plan view” means “A and B spaced (e.g., spaced apart) from each other in a two-dimensional view cut in a direction perpendicular to the substrate 100 (see FIG. 3).”

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

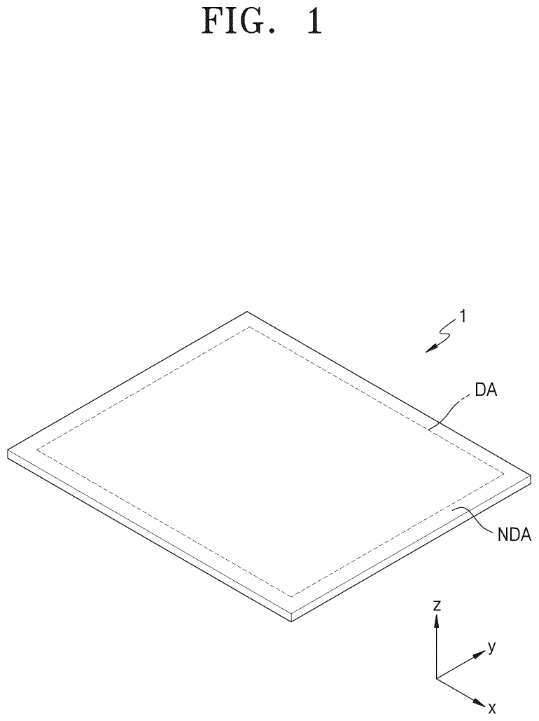

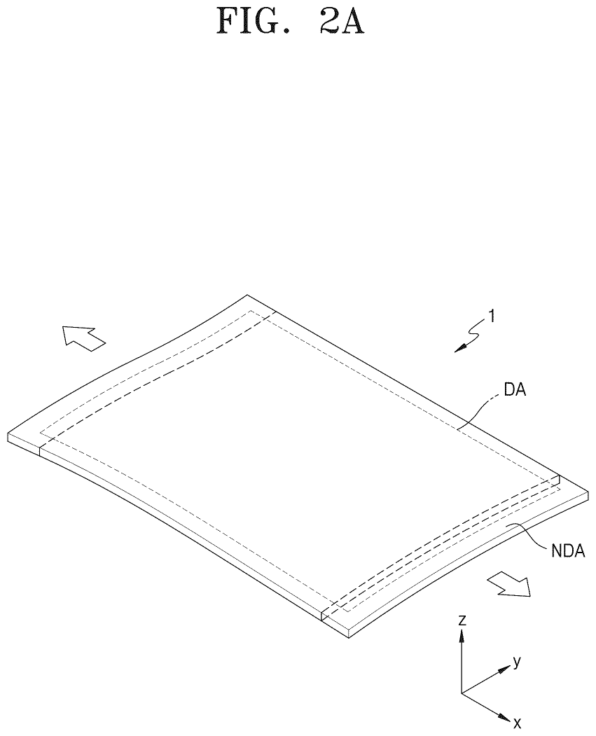

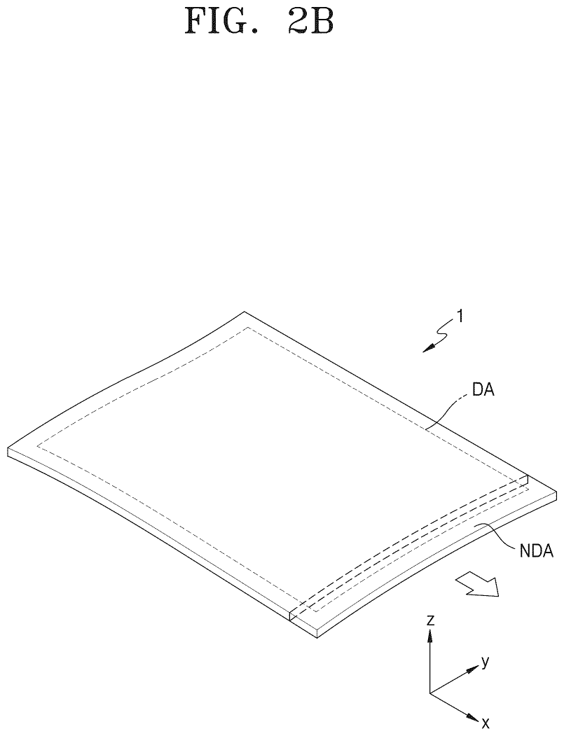

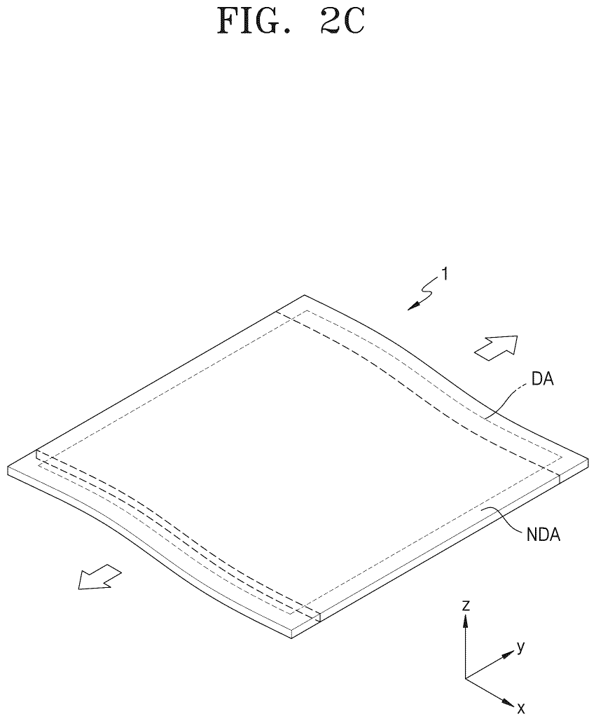

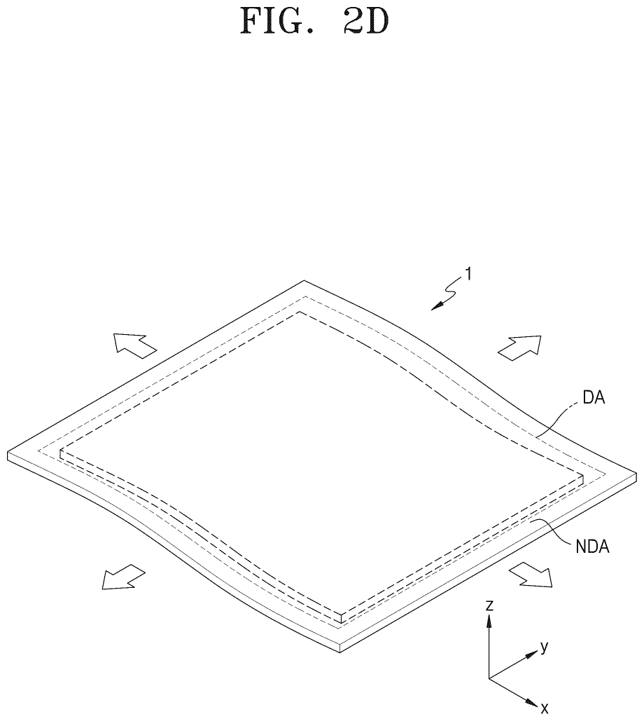

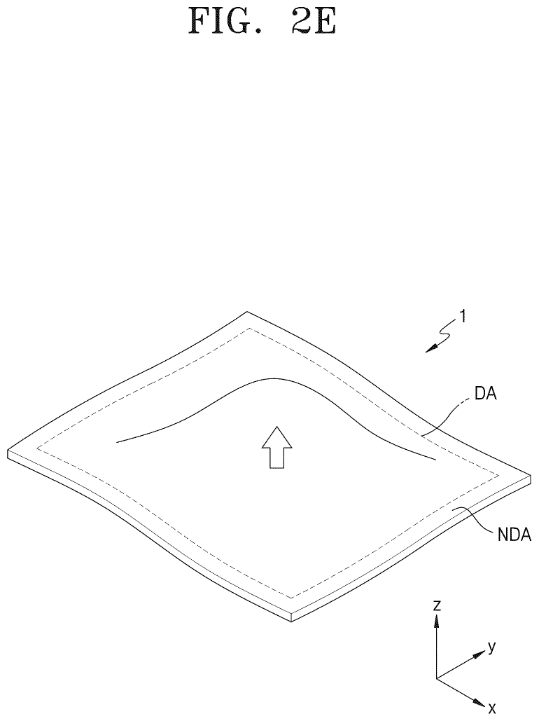

FIG. 1 is a perspective view schematically illustrating a display apparatus, according to one or more embodiments. FIGS. 2A and 2B are perspective views illustrating a state where the display apparatus of FIG. 1 is stretched in a first direction. FIG. 2C is a perspective view illustrating a state where the display apparatus of FIG. 1 is stretched in a second direction. FIG. 2D is a perspective view illustrating a state where the display apparatus of FIG. 1 is stretched in the first direction and the second direction. FIG. 2E is a perspective view illustrating a state where the display apparatus of FIG. 1 is stretched in a third direction.

Referring to FIG. 1, a display apparatus 1 may include a display area DA and a non-display area NDA disposed around the display area DA along an edge or a periphery of the display area DA. The display area DA may include a plurality of pixels. The display apparatus 1 may provide a certain image by using light emitted from the plurality of pixels. The non-display area NDA may be disposed outside the display area DA. The non-display area NDA may entirely surround the display area DA.

The display apparatus 1 may be stretched or shrunk in various directions. The display apparatus 1 may be stretched in a first direction (e.g., an x direction and/or a −x direction) by an external force applied by a user or an external object. In one or more embodiments, as shown in FIGS. 2A and 2B, the display area DA and/or the non-display area NDA of the display apparatus 1 may be stretched in the first direction (e.g., the x direction and/or the −x direction). For example, the display area DA and/or the non-display area NDA of the display apparatus 1 may be stretched along the x direction and the −x direction as shown in FIG. 2A, or may be stretched along the x direction with one side fixed as shown in FIG. 2B.

The display apparatus 1 may be stretched in a second direction (e.g., a y direction and/or a −y direction) by an external force applied by a user or an external object. In one or more embodiments, the display area DA and/or the non-display area NDA of the display apparatus 1 may be stretched in the y direction and the −y direction as shown in FIG. 2C. In another embodiment, the display area DA and/or the non-display area NDA of the display apparatus 1 may be stretched in the y direction or the −y direction with one side fixed.

The display apparatus 1 may be stretched in a plurality of directions, for example, in the first direction (e.g., the x direction and/or the −x direction) and the second direction (e.g., the y direction and/or the −y direction) by an external force applied by a user or an external object. The display area DA and/or the non-display area NDA of the display apparatus 1 may be stretched in the ±x direction and the ±y direction as shown in FIG. 2D.

The display apparatus 1 may be stretched in a third direction (e.g., a z direction or a −z direction) by an external force applied by a person's body part or an external object. In one or more embodiments, in FIG. 2E, a part of the display apparatus 1, for example, a portion of the display area DA, protrudes in the z direction. In another embodiment, a part of the display apparatus 1, for example, a portion of the display area DA, may protrude along the −z direction (or recessed along the z direction).

Although the display apparatus 1 is stretched in the first direction, the second direction, and/or the third direction in FIGS. 2A-2E, the present disclosure is not limited thereto. In another embodiment, the display apparatus 1 may be deformed, for example, bent or twisted, into various irregular shapes along two or more axes.

FIG. 3 is a plan view schematically illustrating a part of a display apparatus, according to one or more embodiments.

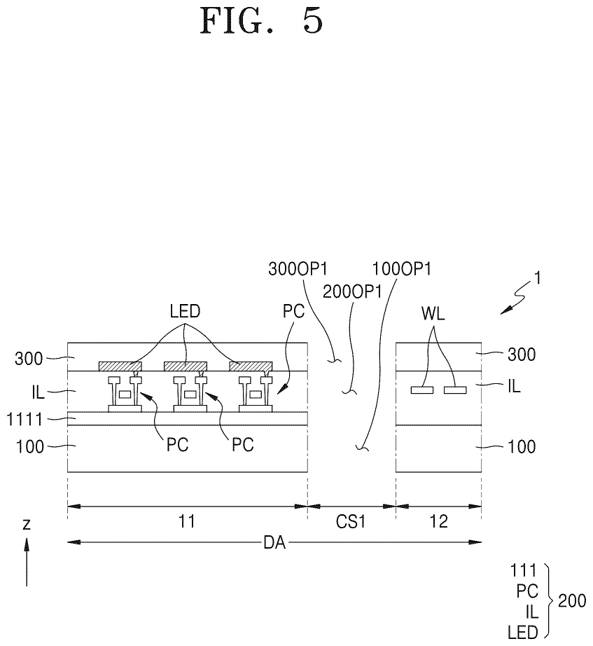

Referring to FIG. 3, the display apparatus 1 includes a plurality of pixels P disposed in the display area DA. Each of the plurality of pixels P may include a light-emitting element LED (see FIG. 5). Each pixel P may emit, for example, red light, green light, blue light, or white light, through the light-emitting element LED (see FIG. 5). The pixel P in the specification may be a pixel that emits red light, green light, blue light, or white light as described above.

Each pixel P may be electrically connected to outer circuits disposed in the non-display area NDA.

The non-display area NDA may include a first non-display area NDA1, a second non-display area NDA2, a third non-display area NDA3, and a fourth non-display area NDA4. The first non-display area NDA1 and the second non-display area NDA2 may be spaced (e.g., spaced apart) from each other with the display area DA therebetween. The third non-display area NDA3 and the fourth non-display area NDA4 may be spaced (e.g., spaced apart) from each other with the display area DA therebetween.

In the non-display area NDA, a first scan driving circuit 101, a second scan driving circuit 103, a terminal 104, a data driving circuit 105, a driving voltage supply wiring 106, and a common voltage supply wiring 107 may be disposed.

The first scan driving circuit 101 may provide a scan signal to each pixel P through a scan line SL. The second scan driving circuit 103 and the first scan driving circuit 101 may be parallel to each other with the display area DA therebetween. Some of the pixels P disposed in the display area DA may be electrically connected to the first scan driving circuit 101, and the rest may be electrically connected to the second scan driving circuit 103.

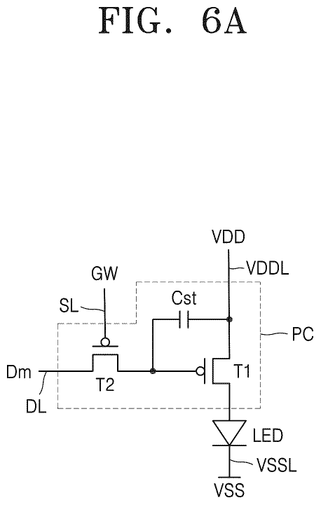

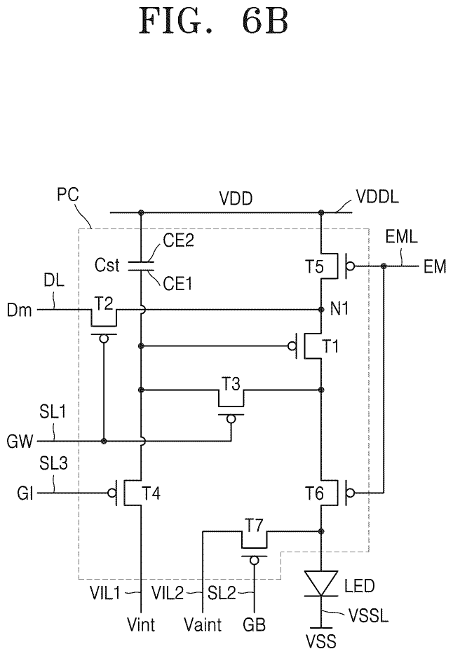

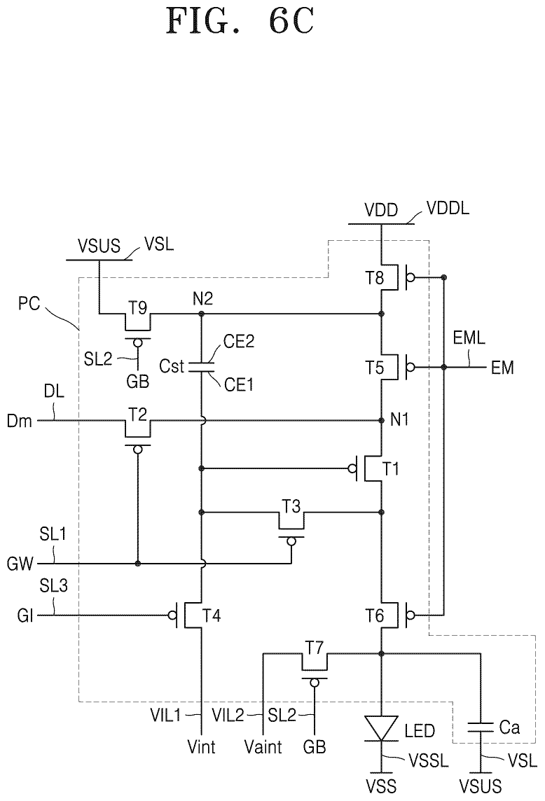

The terminal 104 may be disposed on a side of the substrate 100. The terminal 104 may be exposed without being covered by an insulating layer, and may be electrically connected to a printed circuit board PCB. A terminal PCB-P of the printed circuit board PCB may be electrically connected to the terminal 104 of the display apparatus 1. The printed circuit board PCB transmits a signal or power of a controller to the display apparatus 1. A control signal generated by the controller may be transmitted to the first scan driving circuit 101 and the second scan driving circuit 103 through the printed circuit board PCB. The controller may provide a driving voltage VDD (see FIG. 6A) and a common voltage VSS (see FIG. 6A) to the driving voltage supply wiring 106 and the common voltage supply wiring 107 through a driving wiring 108 and a common wiring 109, respectively. The driving voltage VDD (see FIG. 6A) may be provided to the pixel P through a driving voltage line VDDL connected to the driving voltage supply wiring 106, and the common voltage VSS (see FIG. 6A) may be provided to a counter electrode of the pixel P connected to the common voltage supply wiring 107.

The data driving circuit 105 is electrically connected to a data line DL. A data signal of the data driving circuit 105 may be provided to each pixel P through a data wiring 110 connected to the terminal 104 and the data line DL connected to the data wiring 110.

FIG. 3 shows that the data driving circuit 105 is disposed on the printed circuit board PCB. However, in one or more embodiments, the data driving circuit 105 may be disposed on the substrate 100. For example, the data driving circuit 105 may be disposed between the terminal 104 and the driving voltage supply wiring 106.

The driving voltage supply wiring 106 may include a first sub-wiring 1110 and a second sub-wiring 1120 extending parallel to each other along the first direction (e.g., the x direction and/or the −x direction) with the display area DA therebetween. The common voltage supply wiring 107 may have a loop shape with one side open and may partially surround the display area DA.

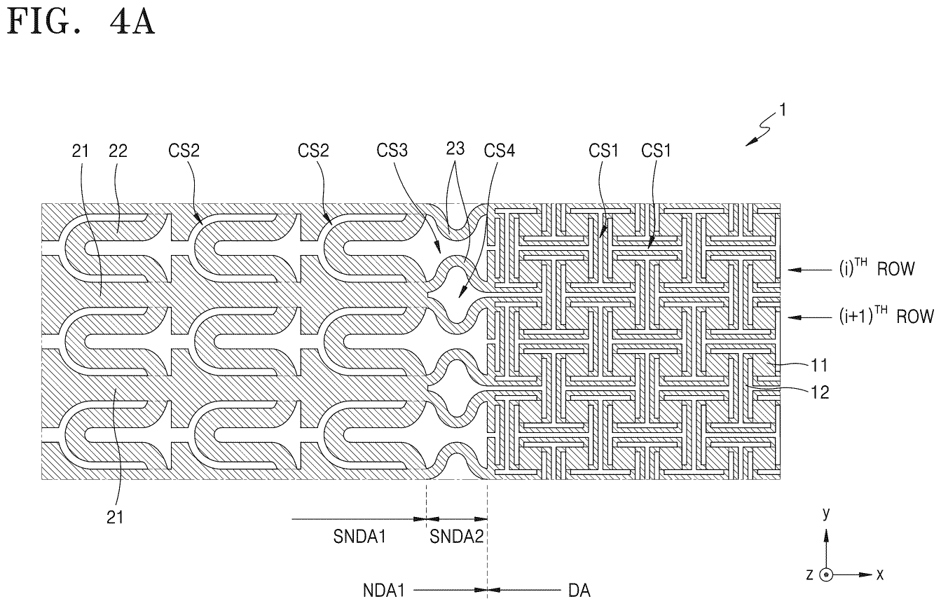

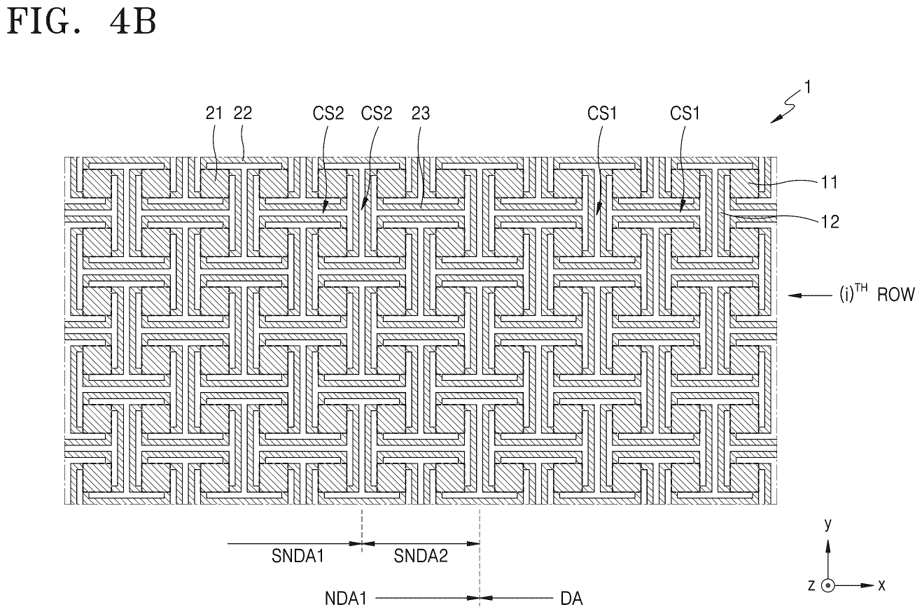

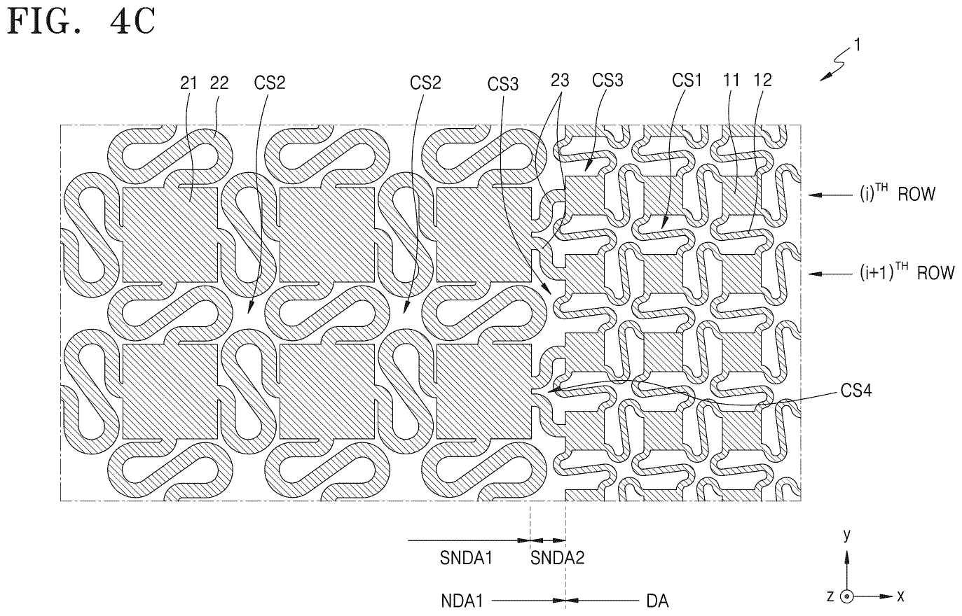

FIG. 4A is a plan view illustrating a part of a display apparatus, according to one or more embodiments.

Referring to FIG. 4A, the display apparatus 1 may include first island portions 11 spaced (e.g., spaced apart) from each other in the first direction (e.g., the x direction or the −x direction) and the second direction (e.g., the y direction or the −y direction) and first bridge portions 12 connecting adjacent first island portions 11 in the display area DA.

Each first island portion 11 may be connected to a plurality of first bridge portions 12. For example, each first island portion 11 may be connected to four first bridge portions 12. Two first bridge portions 12 may be disposed on both sides of the first island portion 11 along the first direction (e.g., the x direction or the −x direction), and the remaining two first bridge portions 12 may be disposed on both sides of the first island portion 11 along the second direction (e.g., the y direction or the-y direction). In one or more embodiments, the four first bridge portions 12 may be respectively connected to four sides of the first island portion 11. Each of the four first bridge portions 12 may be adjacent to each of corners of the first island portion 11.

The first bridge portions 12 may be spaced (e.g., spaced apart) from each other by a first opening CS1 located between the first bridge portions 12. In one or more embodiments a first opening CS1 having a substantially H shape and a first opening CS1 having a substantially I shape obtained by rotating the H shape by 90 degrees may be alternately and repeatedly arranged along the first direction (e.g., the x direction or the −x direction) and the second direction (e.g., the y direction or the −y direction). Both ends of each first bridge portion 12 may be respectively connected to adjacent first island portions 11, and one side of each first bridge portion 12 may be spaced (e.g., spaced apart) from one side of the adjacent first island portion 11 and/or one side of another first bridge portion 12 by the first opening CS1.

The display apparatus 1 may include second island portions 21 spaced (e.g., spaced apart) from each other and second bridge portions 22 connecting adjacent second island portions 21 in the non-display area, for example, the first non-display area NDA1 of FIG. 4A.

Each second island portion 21 may extend in the first direction (e.g., the x direction or the −x direction). The second island portions 21 may be spaced (e.g., spaced apart) from each other in the second direction (e.g., y direction or −y direction) intersecting the first direction (e.g., x direction or −x direction). Each second island portion 21 may include drivers of the first scan driving circuit 101 (see FIG. 3) and the second scan driving circuit 103 (see FIG. 3) described with reference to FIG. 3.

The second bridge portion 22 may have a serpentine shape. A length of the second bridge portion 22 may be greater than a shortest distance between the second island portions 21 adjacent to each other along the second direction (e.g., the y direction or the −y direction). In one or more embodiments, the second bridge portion 22 may have a substantially omega (Ω) shape that is convex toward the first direction (e.g., the x direction or the −x direction). The second bridge portions 22 may be disposed between adjacent second island portions 21, but may be spaced (e.g., spaced apart) from each other.

The second bridge portions 22 between adjacent second island portions 21 may be spaced (e.g., spaced apart) from each other by a second opening CS2. Between adjacent second island portions 21, the second openings CS2 and the second bridge portions 22 may be alternately arranged along the first direction (e.g., the x direction or the −x direction). The second openings CS2 may have the same shape. Both ends of each second bridge portion 22 may be connected to adjacent second island portions 21, and one side of each second bridge portion 22 may be spaced (e.g., spaced apart) from one side of the adjacent second island portion 21 and/or one side of another second bridge portion 22 by the second opening CS2.

A second island portion 21 disposed in the first non-display area NDA1 may correspond to the first island portions 11 of a plurality of rows arranged in the display area DA. For example, a second island portion 21 disposed in the first non-display area NDA1 may correspond to the first island portions 11 arranged in an (i)^{th} row and the first island portions 11 arranged in an (i+1)^{th} row in the display area DA (where i is a positive number greater than 0). Although one second island portion 21 corresponds to the first island portions 11 arranged in two rows in FIG. 4A, the present disclosure is not limited thereto. In another embodiment, the second island portion 21 disposed in the first non-display area NDA1 may correspond to the first island portions 11 arranged in n rows in the display area DA (where n is a positive number of 3 or more).

The non-display area, for example, the first non-display area NDA1, may include a first sub-non-display area SNDA1 in which the second island portions 21 and the second bridge portions 22 are disposed, and a second sub-non-display area SNDA2 between the first sub-non-display area SNDA1 and the display area DA. In the second sub-non-display area SNDA2, third bridge portions 23 for connecting the display area DA and the first sub-non-display area SNDA1 to each other may be disposed. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. In one or more embodiments, a shape of the third bridge portion 23 may be different from a shape of each of the first bridge portion 12 and the second bridge portion 22. In one or more embodiments, as shown in FIG. 4A, the third bridge portion 23 may have a substantially omega (Ω) shape that is convex toward the second direction (e.g., the y direction or the −y direction). Adjacent third bridge portions 23 arranged along the second direction (e.g., the y direction or the −y direction) may have a symmetrical structure in which one of the adjacent third bridge portions 23 is convex in the y direction and the other is convex in the −y direction. A third opening CS3 and a fourth opening CS4 having different shapes may be repeated between the third bridge portions 23. A width of the third bridge portion 23 may be different from a width of the first bridge portion 12 and a width of the second bridge portion 22. In one or more embodiments, a width of the third bridge portion 23 may be greater than a width of the first bridge portion 12 and may be less than a width of the second bridge portion 22.

In FIG. 4A, the second island portion 21 and the second bridge portion 22 of the non-display area, for example, the first non-display area NDA1, have different shapes from the first island portion 11 and the first bridge portion 12 of the display area DA. In another embodiment, the second island portion 21 and the second bridge portion 22 of the non-display area may have the same shape as the first island portion 11 and the first bridge portion 12 of the display area DA, respectively.

FIG. 4B is a plan view illustrating a part of a display apparatus according to one or more embodiments.

Referring to FIG. 4B, the display apparatus 1 includes the first island portions 11 spaced (e.g., spaced apart) from each other and the first bridge portions 12 spaced (e.g., spaced apart) from each other by the first opening CS1 and connecting adjacent first island portions 11 in the display area DA. A structure of the display area DA of FIG. 4B may be the same as a structure of the display area DA described with reference to FIG. 4A.

The display apparatus 1 may include the second island portions 21 and the second bridge portions 22 in the non-display area, for example, the first non-display area NDA1. In one or more embodiments, the second island portions 21 and the second bridge portions 22 may have substantially the same shape as the first island portions 11 and the first bridge portions 12, respectively.

The second island portions 21 may be spaced (e.g., spaced apart) from each other in the first direction (e.g., the x direction or the −x direction) and the second direction (e.g., the y direction or the −y direction) in the non-display area, for example, the first non-display area NDA1. Each of the second bridge portions 22 may connect adjacent second island portions 21. The second bridge portions 22 may be spaced (e.g., spaced apart) from each other by the second opening CS2 located between the second bridge portions 22.

The second opening CS2 may have substantially the same shape as the first opening CS1. For example, the second opening CS2 having a substantially H shape and the second opening CS2 having a substantially I shape may be alternately and repeatedly arranged in the non-display area, for example, the first non-display area NDA1. Both ends of each second bridge portion 22 may be respectively connected to adjacent second island portions 21, and one side of each second bridge portion 22 may be spaced (e.g., spaced apart) from one side of the adjacent second island portion 21 and/or one side of another second bridge portion 22 by the second opening CS2.

Each second island portion 21 may be connected to four second bridge portions 22. Each second island portion 21 may include drivers of the first scan driving circuit 101 (see FIG. 3) and/or the second scan driving circuit 103 (see FIG. 3) described with reference to FIG. 3.

The second island portions 21 of one row disposed in the first non-display area NDA1 may correspond to the first island portions 11 of one row arranged in the display area DA. For example, the second island portions 21 arranged in an (i)^{th} row along the first direction (e.g., the x direction or the −x direction) in the first non-display area NDA1 may correspond to the first island portions 11 arranged in the same row, for example, an (i)^{th} row, in the display area DA (where i is a positive number greater than 0).

The display apparatus 1 may include the third bridge portions 23 disposed in the second sub-non-display area SNDA2 for connecting the display area DA and the first sub-non-display area SNDA1 to each other. The non-display area, for example, the first non-display area NDA1, may include the first sub-non-display area SNDA1 in which the second island portions 21 and the second bridge portions 22 are disposed, and the second sub-non-display area SNDA2 including the third bridge portions 23 and located between the first sub-non-display area SNDA1 and the display area DA. The third bridge portion 23 may be substantially the same as the first bridge portion 12 and the second bridge portion 22. For example, a width of the third bridge portion 23 may be the same as a width of the first bridge portion 12 and a width of the second bridge portion 22.

FIG. 4C is a plan view illustrating a display apparatus, according to one or more embodiments.

Referring to FIG. 4C, the display apparatus 1 may include the first island portions 11 spaced (e.g., spaced apart) from each other in the first direction (e.g., the x direction or the −x direction) and the second direction (e.g., the y direction or the −y direction) and the first bridge portions 12 connecting adjacent first island portions 11 in the display area DA.

The first bridge portions 12 may be spaced (e.g., spaced apart) from each other by the first opening CS1 located between the first bridge portions 12. The first bridge portion 12 may be a serpentine shape. For example, as shown in FIG. 4C, the first bridge portion 12 may have a substantially ‘alphabet S’ shape.

Each first island portion 11 may be connected to a plurality of first bridge portions 12. For example, each first island portion 11 may be connected to four first bridge portions 12. Two first bridge portions 12 may be disposed on both sides of the first island portion 11 along the first direction (e.g., the x direction or the −x direction), and the remaining two first bridge portions 12 may be disposed on both sides of the first island portion 11 along the second direction (e.g., the y direction or the −y direction). The four first bridge portions 12 may be respectively connected to four sides (or four corners) of the first island portion 11. Each of the four first bridge portions 12 may be adjacent to each of the corners of the first island portion 11.

The display apparatus 1 may include the second island portions 21 spaced (e.g., spaced apart) from each other in the first direction (e.g., the x direction or the −x direction) and the second direction (e.g., the y direction or the −y direction) and the second bridge portions 22 connecting adjacent second island portions 21 in the non-display area, for example, the first non-display area NDA1 of FIG. 4C.

The second bridge portions 22 may be spaced (e.g., spaced apart) from each other by the second opening CS2 disposed between the second bridge portions 22. The second bridge portion 22 may have a serpentine shape. For example, as shown in FIG. 4C, the second bridge portion 22 may have a substantially ‘alphabet S’ shape. A size and/or a width of the second bridge portion 22 may be different from a size and/or a width of the first bridge portion 12. For example, a size and/or a width of the second bridge portion 22 may be greater than a size and/or a width of the first bridge portion 12. A radius of curvature of a rounded portion of the second bridge portion 22 may be different from a radius of curvature of a rounded portion of the first bridge portion 12. For example, a radius of curvature of a rounded portion of the second bridge portion 22 may be greater than a radius of curvature of a rounded portion of the first bridge portion 12.

Each second island portion 21 may be connected to a plurality of second bridge portions 22. Each second island portion 21 may be connected to four second bridge portions 22. Two second bridge portions 22 may be disposed on both sides of the second island portion 21 along the first direction (e.g., the x direction or the −x direction), and the remaining two second bridge portions 22 may be disposed on both sides of the second island portion 21 along the second direction (e.g., the y direction or the −y direction). In one or more embodiments, the four second bridge portions 22 may be respectively connected to four sides of the second island portion 21. Each second bridge portion 22 may be connected to a central portion of each side of the second island portion 21.

The second island portions 21 of any one row disposed in the first non-display area NDA1 may correspond to the first island portions 11 of a plurality of rows arranged in the display area DA. For example, the second island portions 21 of any one row disposed in the first non-display area NDA1 may correspond to the first island portions 11 arranged in an (i)^{th} row and the first island portions 11 arranged in an (i+1)^{th} row of the display area DA (where i is a positive number greater than 0). In another embodiment, the second island portions 21 of any one row may correspond to the first island portions 11 arranged in n rows (where n is a positive number of 3 or more).

The non-display area, for example, the first non-display area NDA1, may include the first sub-non-display area SNDA1 in which the second island portions 21 and the second bridge portions 22 are disposed, and the second sub-non-display area SNDA2 between the first sub-non-display area SNDA1 and the display area DA. The third bridge portions 23 for connecting the display area DA and the first sub-non-display area SNDA1 to each other may be disposed in the second sub-non-display area SNDA2. One end of the third bridge portion 23 may be connected to the second island portion 21, and the other end of the third bridge portion 23 may be connected to the first island portion 11. For example, one end of the third bridge portion 23 may be connected to a central portion of one side of the second island portion 21, and the other end of the third bridge portion 23 may be connected to a central portion of one side of the first island portion 11.

The third bridge portion 23 may have a serpentine shape. In one or more embodiments, a shape of the third bridge portion 23 may be different from a shape of each of the first bridge portion 12 and the second bridge portion 22. A width of the third bridge portion 23 may be different from a width of the first bridge portion 12 and a width of the second bridge portion 22. A width of the third bridge portion 23 may be greater than a width of the first bridge portion 12 and may be less than a width of the second bridge portion 22. The third opening CS3 and the fourth opening CS4 having different shapes may be alternately disposed between the third bridge portions 23 in the second direction (e.g., the y direction or the −y direction).

FIG. 5 is a cross-sectional view illustrating a first island portion and a first bridge portion disposed in a display area of a display apparatus, according to one or more embodiments.

Referring to FIG. 5, the first island portion 11 and the first bridge portion 12 disposed in the display area DA may be spaced (e.g., spaced apart) from each other with the first opening CS1 therebetween. The first island portion 11 may include light-emitting elements LED and a circuit, for example, a pixel driving circuit unit PC, electrically connected to each of the light-emitting elements LED to drive each of the light-emitting elements LED, and the first bridge portion 12 may include a wiring WL electrically connected to the pixel driving circuit units PC disposed in adjacent first island portions 11.

Regarding the first island portion 11, a buffer layer 1111 including an inorganic insulating material may be disposed on a substrate 100, and the pixel driving circuit unit PC may be disposed on the buffer layer 1111. An insulating layer IL including an inorganic insulating material and/or an organic insulating material may be disposed between the pixel driving circuit unit PC and the light-emitting element LED. The light-emitting element LED may be disposed on the insulating layer IL and may be electrically connected to the corresponding pixel driving circuit unit PC. The light-emitting elements LED may emit light of different colors or light of the same color. In one or more embodiments, the light-emitting elements LED may emit red light, green light, and/or blue light. In one or more embodiments, the light-emitting elements LED may emit white light. In another embodiment, the light-emitting elements LED may respectively emit red light, green light, blue light, and white light.

The substrate 100 may include a polymer resin such as polyethersulfone, polyarylate, polyether imide, polyethylene naphthalate, polyethylene terephthalate, polyphenylene sulfide, polyimide, polycarbonate, cellulose triacetate, and/or cellulose acetate propionate. In one or more embodiments, the substrate 100 may have a single-layer structure including the polymer resin. In another embodiment, the substrate 100 may have a multi-layer structure including a base layer including the polymer resin and a barrier layer including an inorganic insulating material. The substrate 100 including the polymer resin may be flexible, rollable, and/or bendable.

In one or more embodiments, although three pixel driving circuit units PC are disposed in each first island portion 11 and three light-emitting elements LED are respectively connected to the pixel driving circuit units PC in FIG. 5, the present disclosure is not limited thereto. In another embodiment, the number of pixel driving circuit units PC and light-emitting elements LED disposed in the first island portion 11 may be one, two, or four or more.

An encapsulation layer 300 may be disposed on the light-emitting element LED, and may protect the light-emitting element LED from an external force and/or moisture penetration. The encapsulation layer 300 may include an inorganic encapsulation layer and/or an organic encapsulation layer. In one or more embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In one or more embodiments, the encapsulation layer 300 may include urethane epoxy acrylate. The encapsulation layer 300 may include a photosensitive material such as a photoresist.

Regarding the first bridge portion 12, the insulating layer IL including an organic insulating material may be disposed on the substrate 100. The first bridge portion 12 that is relatively highly deformed when the display apparatus 1 is stretched may not include a layer including an inorganic insulating material that is prone to cracks, unlike the first island portion 11.

In one or more embodiments, the substrate 100 corresponding to the first bridge portion 12 may have the same stacked structure as the substrate 100 corresponding to the first island portion 11. In one or more embodiments, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a stacked structure different from that of the substrate 100 corresponding to the first island portion 11. In some embodiments, the substrate 100 corresponding to the first island portion 11 may have a multi-layer structure including a base layer including a polymer resin and a barrier layer including an inorganic insulating material, and the substrate 100 corresponding to the first bridge portion 12 may have a structure including a polymer resin layer without a layer including an inorganic insulating material.

As described above, the wirings WL of the first bridge portion 12 may be signal lines (e.g., a gate line and a data line) for providing an electrical signal to a transistor included in the pixel driving circuit unit PC of the first island portion 11 or voltage lines (e.g., a driving voltage line and an initialization voltage line) for providing a voltage. The encapsulation layer 300 may also be disposed in the first bridge portion 12. In another embodiment, the encapsulation layer 300 may not be disposed in the first bridge portion 12.

Referring to FIGS. 4A-4C and 5, the substrate 100 corresponding to the first island portion 11 and the substrate 100 corresponding to the first bridge portion 12 may be connected to each other. In other words, the plan view of FIGS. 4A-4C may be substantially the same as a plan view of the substrate 100 of FIG. 5. In other words, the substrate 100 may include an area corresponding to the first island portion 11, an area corresponding to the first bridge portion 12, and an opening 100OP1 having the same shape as that of the first opening CS1.

Likewise, the encapsulation layer 300 corresponding to the first island portion 11 and the encapsulation layer 300 corresponding to the first bridge portion 12 may be connected to each other. For example, the plan view of FIGS. 4A-4C may be substantially the same as a plan view of the encapsulation layer 300. In other words, the encapsulation layer 300 may include an area corresponding to the first island portion 11, an area corresponding to the first bridge portion 12, and an opening 300OP1 having the same shape as that of the first opening CS1.

A circuit-light-emitting element layer 200 between the substrate 100 and the encapsulation layer 300 may include the buffer layer 1111, the pixel driving circuit unit PC, the wiring WL, the insulating layer IL, and the light-emitting element LED. Like the substrate 100, the plan view of FIGS. 4A-4C may be substantially the same as a plan view of the circuit-light-emitting element layer 200. In other words, the circuit-light-emitting element layer 200 may include an opening 200OP1 having the same shape as that of the first opening CS1.

FIGS. 6A-6C are equivalent circuit diagrams illustrating a sub-pixel of a display apparatus, according to one or more embodiments.

Referring to FIG. 6A, the light-emitting element LED corresponding to a sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to a signal line and a voltage line. The signal line may include a gate line such as a scan line SL and a data line DL, and the voltage line may include a driving voltage line VDDL and a common voltage line VSSL.

The second transistor T2 may be electrically connected to the scan line SL and the data line DL. The scan line SL may provide a scan signal GW to a gate electrode of the second transistor T2. The second transistor T2 may transmit a data signal Dm input from the data line DL to the gate electrode of the first transistor T1 according to the scan signal GW input from the scan line SL.

The storage capacitor Cst may be electrically connected to the second transistor T2 and the driving voltage line VDDL, and may store a voltage corresponding to a difference between a voltage received from the second transistor T2 and a driving voltage VDD supplied by the driving voltage line VDDL.

The first transistor T1 is a driving transistor and may control driving current flowing through the light-emitting element LED. The first transistor T1 may be connected to the driving voltage line VDDL and the storage capacitor Cst. The first transistor T1 may control the driving current flowing through the light-emitting element LED from the driving voltage line VDDL in response to a value of the voltage stored in the storage capacitor Cst. The light-emitting element LED may emit light having a certain luminance due to the driving current. A first electrode of the light-emitting element LED may be electrically connected to the first transistor T1, and a second electrode of the light-emitting element LED may be electrically connected to a common voltage line VSSL that supplies a common voltage VSS.

Although the pixel driving circuit unit PC includes two transistors and one storage capacitor in FIG. 6A, in another embodiment, the pixel driving circuit unit PC may include three or more transistors.

Referring to FIG. 6B, the pixel driving circuit unit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit unit PC is electrically connected to signal lines and voltage lines. The signal lines may include gate lines such as a first scan line SL1, a second scan line SL2, a third scan line SL3, and an emission control line EML, and a data line DL. The voltage lines may include first and second initialization voltage lines VIL1 and VIL2, a driving voltage line VDDL, and a common voltage line VSSL.

The driving voltage line VDDL may transmit a driving voltage VDD to the first transistor T1. The first initialization voltage line VIL1 may transmit a first initialization voltage Vint for initializing the first transistor T1 to the pixel driving circuit unit PC. The second initialization voltage line VIL2 may transmit a second initialization voltage Vaint for initializing a first electrode of the light-emitting element LED to the pixel driving circuit unit PC.

The first transistor T1 may be electrically connected to the driving voltage line VDDL via the fifth transistor T5, and may be electrically connected to the light-emitting element LED via the sixth transistor T6. The first transistor T1 functions as a driving transistor, and receives a data signal Dm according to a switching operation of the second transistor T2 and supplies driving current to the light-emitting element LED.

The second transistor T2 is a data write transistor and is electrically connected to the first scan line SL1 and the data line DL. The second transistor T2 is electrically connected to the driving voltage line VDDL via the fifth transistor T5. The second transistor T2 is turned on according to a first scan signal GW received through the first scan line SL1 to perform a switching operation of transmitting the data signal Dm received through the data line DL to a first node N1 connected to a first electrode of the first transistor T1.

The third transistor T3 is electrically connected to the first scan line SL1 and is electrically connected to the light-emitting element LED via the sixth transistor T6. The third transistor T3 may be turned on according to the first scan signal GW received through the first scan line SL1 to diode-connect the first transistor T1 as the third transistor T3 is connected between a second electrode and a gate electrode of the first transistor T1.

The fourth transistor T4 is a first initialization transistor and is electrically connected to the third scan line SL3 and the first initialization voltage line VIL1. The fourth transistor T4 is turned on according to a third scan signal GI received through the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit disposed in a previous row with respect to the pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML, and are concurrently (e.g., simultaneously) turned on according to an emission control signal EM received through the emission control line EML to form a current path through which the driving current may flow from the driving voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 may be turned on according to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The storage capacitor Cst includes a first electrode CE1 and the second electrode CE2. The first electrode CE1 is electrically connected to the gate electrode of the first transistor T1, and the second electrode CE2 is electrically connected to the driving voltage line VDDL. The storage capacitor Cst may maintain a voltage applied to the gate electrode of the first transistor T1 by storing and maintaining a voltage corresponding to a voltage difference between the driving voltage line VDDL and the gate electrode of the first transistor T1.

Referring to FIG. 6C, the pixel driving circuit unit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit unit PC is electrically connected to signal lines and voltage lines. The signal lines may include gate lines such as a first scan line SL1, a second scan line SL2, a third scan line SL3, and an emission control line EML, and a data line DL. The voltage lines may include first and second initialization voltage lines VIL1 and VIL2, a sustain voltage line VSL, a driving voltage line VDDL and a common voltage line VSSL.

The driving voltage line VDDL may transmit a driving voltage VDD to the first transistor T1. The first initialization voltage line VIL1 may transmit a first initialization voltage Vint for initializing the first transistor T1 to the pixel driving circuit unit PC. The second initialization voltage line VIL2 may transmit a second initialization voltage Vaint for initializing a first electrode of the light-emitting element LED to the pixel driving circuit unit PC. The sustain voltage line VSL may provide a sustain voltage VSUS to a second node N2, for example, a second electrode CE2 of the storage capacitor Cst, in an initialization period and a data write period.

The first transistor T1 may be electrically connected to the driving voltage line VDDL via the fifth transistor T5 and the eighth transistor T8, and may be electrically connected to the light-emitting element LED via the sixth transistor T6. The first transistor T1 functions as a driving transistor, and may supply driving current to the light-emitting element LED by receiving a data signal Dm according to a switching operation of the second transistor T2.

The second transistor T2 is electrically connected to the first scan line SL1 and the data line DL, and is electrically connected to the driving voltage line VDDL via the fifth transistor T5 and the eighth transistor T8. The second transistor T2 is turned on according to a first scan signal GW received through the first scan line SL1 to perform a switching operation of transmitting the data signal Dm received through the data line DL to a first node N1.

The third transistor T3 is electrically connected to the first scan line SL1 and is electrically connected to the light-emitting element LED via the sixth transistor T6. The third transistor T3 is turned on according to the first scan signal GW received through the first scan line SL1 to diode-connect the first transistor T1 and compensate for a threshold voltage of the first transistor T1.

The fourth transistor T4 is electrically connected to the third scan line SL3 and the first initialization voltage line VIL1, and is turned on according to a third scan signal GI received through the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit disposed in a previous row with respect to the pixel driving circuit unit PC.

The fifth transistor T5, the sixth transistor T6, and the eighth transistor T8 are electrically connected to the emission control line EML, and are concurrently (e.g., simultaneously) turned on according to an emission control signal EM received through the emission control line EML to form a current path through which the driving current may flow from the driving voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst (or the second node N2), and the sustain voltage line VSL. The ninth transistor T9 may be turned on according to the second scan signal GB received through the second scan line SL2 to transmit the sustain voltage VSUS to the second node N2, for example, the second electrode CE2 of the storage capacitor Cst, in the initialization period and the data write period.

The eighth transistor T8 and the ninth transistor T9 may be electrically connected to the second node N2, for example, the second electrode CE2 of the storage capacitor Cst. In one or more embodiments, the eighth transistor T8 may be turned off and the ninth transistor T9 may be turned on in the initialization period and the data write period, and the eighth transistor T8 may be turned on and the ninth transistor T9 may be turned off in an emission period. Because the sustain voltage VSUS is transmitted to the second node N2 in the initialization period and the data write period, the uniformity (e.g., long-range uniformity (LRU)) of luminance of the display apparatus according to a voltage drop of the driving voltage line VDDL may be improved.

The storage capacitor Cst includes a first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to a voltage difference between the first electrode of the light-emitting element LED and the sustain voltage line VSL while the seventh transistor T7 and the ninth transistor T9 are turned on, thereby preventing an increase in black luminance when the sixth transistor T6 is turned off.

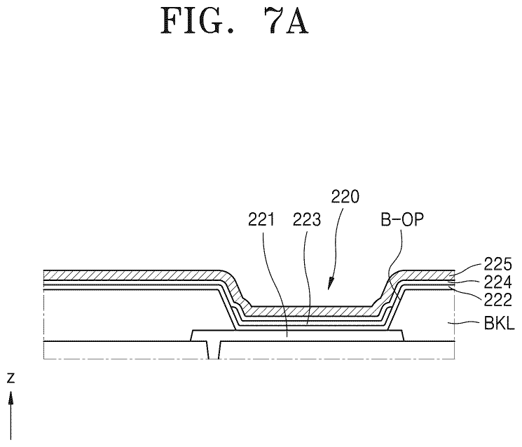

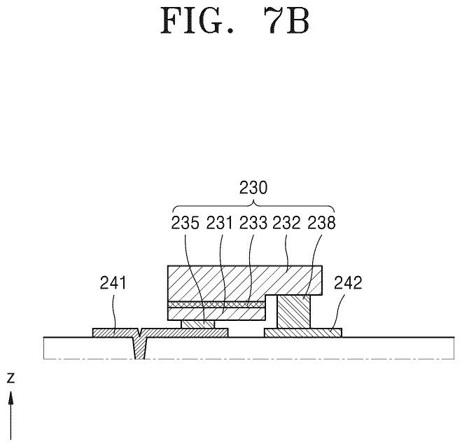

FIG. 7A is a cross-sectional view schematically illustrating a light-emitting element of a display apparatus, according to one or more embodiments.

Referring to FIG. 7A, the light-emitting element LED (see FIG. 5) according to one or more embodiments may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

An edge of the first electrode 221 may be covered by a bank layer BKL including an insulating material. The bank layer BKL may include an opening B-OP overlapping a central portion of the first electrode 221.

The first electrode 221 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), and/or a compound thereof. In another embodiment, the first electrode 221 may further include a layer formed of ITO, IZO, ZnO, AZO, or In₂O₃ over/under the reflective layer.

The emission layer 223 may include a high molecular weight organic material or a low molecular weight organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may be formed of a conductive material having a low work function. For example, the second electrode 225 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 225 may further include a layer formed of ITO, IZO, ZnO, AZO, and/or In₂O₃ on the (semi-)transparent layer including the above material.

FIG. 7B is a cross-sectional view schematically illustrating a light-emitting element of a display apparatus, according to one or more embodiments.

Referring to FIG. 7B, the light-emitting element LED (see FIG. 5) according to one or more embodiments may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242 disposed on (or at) the same layer.

In one or more embodiments, the first semiconductor layer 231 may include a p-type semiconductor layer. The p-type semiconductor layer may be formed of a semiconductor material having a composition formula of InxAlyGa1-x-yN (0≤x≤1, 0≤y≤1, 0≤x+y≤1) selected from among, for example, GaN, AlN, AlGaN, InGaN, InN, InAlGaN, and/or AlInN, and may be doped with a p-type dopant such as Mg, Zn, Ca, Sr, and/or Ba.

The second semiconductor layer 232 may include, for example, an n-type semiconductor layer. The n-type semiconductor layer may be formed of a semiconductor material having a composition formula of InxAlyGa1-x-yN (0≤x≤1, 0≤y≤1, 0≤x+y≤1), selected from among, for example, GaN, AlN, AlGaN, InGaN, InN, InAlGaN, and/or AlInN, and may be doped with an n-type dopant such as Si, Ge, and/or Sn.

The intermediate layer 233 may be an area where electrons and holes recombine to change to a lower energy level and generate light having a corresponding wavelength. The intermediate layer 233 may include a semiconductor material having a composition formula of InxAlyGa1-x-yN (0≤x≤1, 0≤y≤1, 0≤x+y≤1), and may have a single or multi-quantum well (MQW) structure. Also, the intermediate layer 233 may have a quantum wire structure or a quantum dot structure.

Although the first semiconductor layer 231 includes a p-type semiconductor layer and the second semiconductor layer 232 includes an n-type semiconductor layer in FIG. 7B, the present disclosure is not limited thereto. In another embodiment, the first semiconductor layer 231 may include an n-type semiconductor layer, and the second semiconductor layer 232 may include a p-type semiconductor layer.

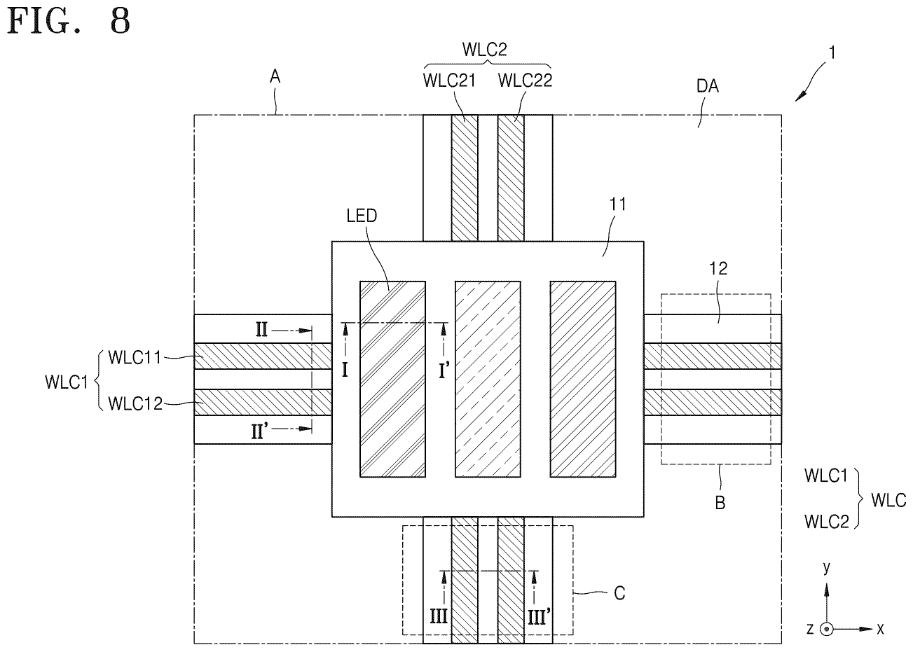

FIG. 8 is an enlarged plan view illustrating a first island portion and a first bridge portion of a display apparatus, according to one or more embodiments.

Referring to FIG. 8, the first island portion 11 disposed in the display area DA may include the light-emitting element LED and the pixel driving circuit unit PC (see FIG. 5) electrically connected to the light-emitting element LED. Although the first island portion 11 includes three light-emitting elements LED in FIG. 8, the present disclosure is not limited thereto. In another embodiment, the number of light-emitting elements LED disposed in the first island portion 11 may be one, two, or four or more.

The first bridge portion 12 may include a plurality of connection wirings WLC electrically connected to the pixel driving circuit units PC (see FIG. 5) disposed in adjacent first island portions 11. As described above, the connection wiring WLC may be a signal line (e.g., a gate line and a data line) for providing an electrical signal to a transistor included in the pixel driving circuit unit PC (see FIG. 5) of the first island portion 11 or a voltage line (e.g., a driving voltage line and an initialization voltage line) for providing a voltage.

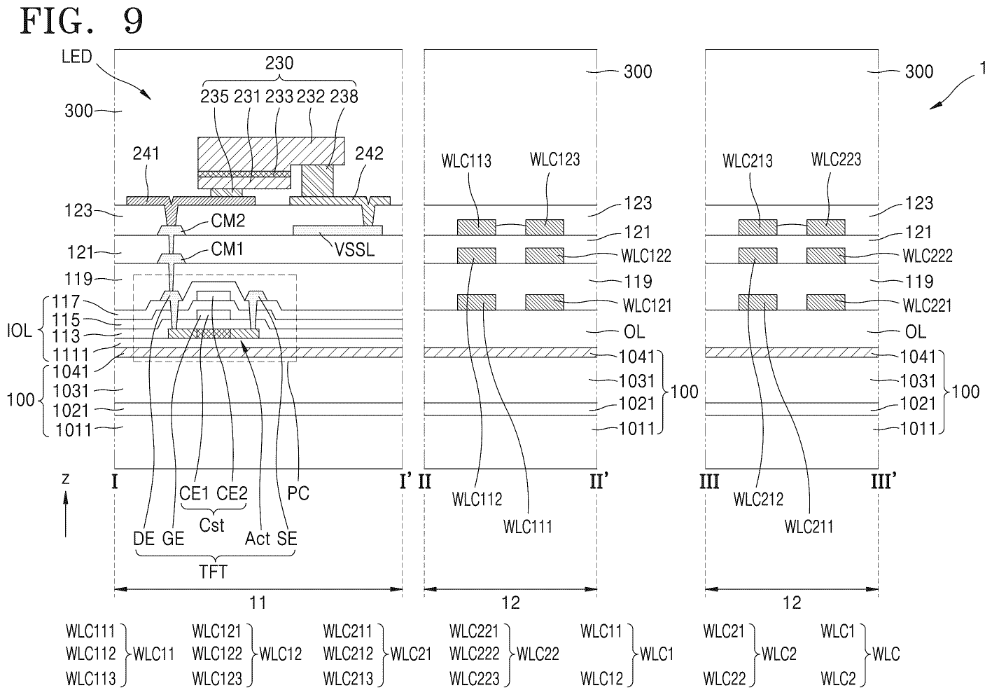

FIG. 9 is a cross-sectional view schematically illustrating a display apparatus, according to one or more embodiments.

In detail, FIG. 9 is a cross-sectional view taken along the lines I-I′, II-II′, and III-III′ of FIG. 8.

Referring to FIG. 9, the substrate 100 corresponding to the first island portion 11 may include a first base layer 1011, a first barrier layer 1021, a second base layer 1031, and a second barrier layer 1041. Each of the first base layer 1011 and the second base layer 1031 may include a polymer resin such as polyethersulfone, polyarylate, polyether imide, polyethylene naphthalate, polyethylene terephthalate, polyphenylene sulfide, polyimide, polycarbonate, cellulose triacetate, and/or cellulose acetate propionate. Each of the first barrier layer 1021 and the second barrier layer 1041 may include an inorganic insulating material such as silicon oxide, silicon nitride, and/or silicon oxynitride.

The buffer layer 1111 may be disposed on the substrate 100, and the pixel driving circuit unit PC may be disposed on the buffer layer 1111. The buffer layer 1111 may include an inorganic insulating material such as silicon oxide, silicon nitride, and/or silicon oxynitride.

A thin-film transistor TFT may include a semiconductor layer Act, a gate electrode GE, a source electrode SE, and a drain electrode DE. Although the thin-film transistor TFT is a top gate type transistor in which the gate electrode GE is disposed on the semiconductor layer Act with a gate insulating layer 113 therebetween in FIG. 9, in another embodiment, the thin-film transistor TFT may be a bottom gate type transistor.

The semiconductor layer Act may include polysilicon. Alternatively, the semiconductor layer Act may include amorphous silicon, an oxide semiconductor, and/or an organic semiconductor. The gate electrode GE may include a low-resistance metal material. The gate electrode GE may include a conductive material including molybdenum (Mo), aluminum (Al), copper (Cu), and/or titanium (Ti), and may have a single or multi-layer structure including the above material.

The gate insulating layer 113 between the semiconductor layer Act and the gate electrode GE may include an inorganic insulating material such as silicon oxide, silicon nitride, silicon oxynitride, aluminum oxide, or/or titanium oxide. The gate insulating layer 113 may have a single or multi-layer structure including the above material and may be disposed on the buffer layer 1111 covering the semiconductor layer Act.

The source electrode SE and the drain electrode DE may be disposed on (or at) the same layer, for example, the second interlayer insulating layer 117, and may include the same material. Each of the source electrode SE and the drain electrode DE may include a conductive material and may have a single or multi-layer structure. The second interlayer insulating layer 117 may include an inorganic insulating material such as silicon oxide, nitrogen oxide, silicon oxynitride, aluminum oxide, and/or titanium oxide, and may have a single or multi-layer structure including the above material. The source electrode SE and the drain electrode DE may be connected to a source region and a drain region of the semiconductor layer Act via corresponding contact holes penetrating the second interlayer insulating layer 117, first interlayer insulating layer 115, and the gate insulating layer 113. The storage capacitor Cst may include the first electrode CE1 and the second electrode CE2 overlapping each other with a first interlayer insulating layer 115 therebetween. The storage capacitor Cst may overlap the thin-film transistor TFT. In this regard, in FIG. 9, the gate electrode GE of the thin-film transistor TFT is the first electrode CE1 of the storage capacitor Cst. In another embodiment, the storage capacitor Cst may not overlap the thin-film transistor TFT. The storage capacitor Cst may be covered by the second interlayer insulating layer 117. The second electrode CE2 of the storage capacitor Cst may include a conductive material and may have a single or multi-layer structure. The first interlayer insulating layer 115 may be disposed between the gate insulating layer 113 and the second interlayer insulating layer 117 and covers the gate electrode GE of the thin-film transistor TFT. The first interlayer insulating layer 115 may include an inorganic insulating material such as silicon oxide, nitrogen oxide, silicon oxynitride, aluminum oxide, and/or titanium oxide, and may have a single or multi-layer structure including the above material.

An inorganic insulating layer IOL on the substrate 100 may include, for example, the buffer layer 1111, the gate insulating layer 113, the first interlayer insulating layer 115, and the second interlayer insulating layer 117.

A first organic insulating layer 119 may be disposed on the second interlayer insulating layer 117, and a second organic insulating layer 121 may be disposed on the first organic insulating layer 119. Each of the first organic insulating layer 119 and the second organic insulating layer 121 may include an organic insulating material such as polyimide.

The common voltage line VSSL may be disposed on the second organic insulating layer 121, and a third organic insulating layer 123 may be disposed on the second organic insulating layer 121 and the common voltage line VSSL. The third organic insulating layer 123 may include an organic insulating material such as polyimide. The common voltage line VSSL may include a conductive material and may have a single or multi-layer structure.

The light-emitting element LED may be disposed on the substrate. In detail, the light-emitting element LED may be disposed on the third organic insulating layer 123. Although the light-emitting element LED in FIG. 9 is the inorganic light-emitting diode 230 described with reference to FIG. 7B, in another embodiment, the light-emitting element LED may be the organic light-emitting diode 220 described with reference to FIG. 7A. The following will be described assuming that the light-emitting element LED is the inorganic light-emitting diode 230.

The first electrode pad 241 and the second electrode pad 242 may be disposed on the third organic insulating layer 123. The first electrode pad 241 may be electrically connected to the thin film transistor TFT (e.g., the drain electrode DE of the thin film transistor TFT) through a first connection electrode CM1 between the first organic insulating layer 119 and the second organic insulating layer 121 and a second connection electrode CM2 between the second organic insulating layer 121 and the third organic insulating layer 123. The inorganic light-emitting diode 230 on the first electrode pad 241 and the second electrode pad 242 is the same as described with reference to FIG. 7B. A light-emitting diode, for example, the inorganic light-emitting diode 230, may be protected by the encapsulation layer 300, and the encapsulation layer 300 may include an inorganic encapsulation layer and/or an organic encapsulation layer or may include an organic material such as resin.

In one or more embodiments, the substrate 100 corresponding to the first bridge portion 12 may have the same stacked structure as the substrate 100 corresponding to the first island portion 11. In one or more embodiments, the substrate 100 corresponding to the first bridge portion 12 may include the first base layer 1011, the first barrier layer 1021, the second base layer 1031, and the second barrier layer 1041. In another embodiment, the substrate 100 corresponding to the first bridge portion 12 may have a stacked structure different from that of the substrate 100 corresponding to the first island portion 11. The substrate 100 corresponding to the first bridge portion 12 may have a structure including the first base layer 1011 and the second base layer 1031.

The inorganic insulating layer IOL may not be disposed on the substrate 100 corresponding to the first bridge portion 12, but an insulating layer OL, the first organic insulating layer 119, the second organic insulating layer 121, and the third organic insulating layer 123 may be disposed on the substrate 100. The encapsulation layer 300 may be disposed on the third organic insulating layer 123. The insulating layer OL may include an organic insulating material such as polyimide. In one or more embodiments, the insulating layer OL may have a thickness corresponding to the inorganic insulating layer IOL. In one or more embodiments, the insulating layer OL may be omitted.

Referring to FIGS. 8 and 9, the connection wiring WLC may include a first connection wiring WLC1 and a second connection wiring WLC2.

The first connection wiring WLC1 may extend in the first direction (e.g., the x direction and/or the −x direction) and may be electrically connected to the first island portion 11. In a plan view, the first connection wiring WLC1 may overlap the first island portion 11. The first connection wiring WLC1 may include a 1-1 connection wiring WLC11 and a 1-2 connection wiring WLC12. The 1-1 connection wiring WLC11 and the 1-2 connection wiring WLC12 may each extend in the first direction (e.g., the x direction and/or the −x direction) and may be spaced (e.g., spaced apart) from each other along the second direction (e.g., the y direction and/or the −y direction). In a plan view, the 1-1 connection wiring WLC11 and the 1-2 connection wiring WLC12 may not overlap each other. Each of the 1-1 connection wiring WLC11 and the 1-2 connection wiring WLC12 may be electrically connected to the first island portion 11.

The 1-1 connection wiring WLC11 may include a 1-11 connection wiring WLC111, a 1-12 connection wiring WLC112, and the 1-13 connection wiring WLC113, and the 1-2 connection wiring WLC12 may include a 1-21 connection wiring WLC121, a 1-22 connection wiring WLC122, and a 1-23 connection wiring WLC123. The 1-11 connection wiring WLC111, the 1-12 connection wiring WLC112, and the 1-13 connection wiring WLC113 may be disposed on different layers. The 1-11 connection wiring WLC111, the 1-12 connection wiring WLC112, and the 1-13 connection wiring WLC113 may be spaced (e.g., spaced apart) from each other along the third direction (e.g., the z direction or the −z direction). The 1-21 connection wiring WLC121, the 1-22 connection wiring WLC122, and the 1-23 connection wiring WLC123 may be disposed on different layers. The 1-21 connection wiring WLC121, the 1-22 connection wiring WLC122, and the 1-23 connection wiring WLC123 may be spaced (e.g., spaced apart) from each other along the third direction (e.g., the z direction or the −z direction).

The 1-11 connection wiring WLC111 may be disposed on (or at) the same layer as the 1-21 connection wiring WLC121, the 1-12 connection wiring WLC112 may be disposed on (or at) the same layer as the 1-22 connection wiring WLC122, and the 1-13 connection wiring WLC113 may be disposed on (or at) the same layer as the 1-23 connection wiring WLC123. For example, the 1-11 connection wiring WLC111 and the 1-21 connection wiring WLC121 may be disposed between the insulating layer OL and the first organic insulating layer 119. The 1-12 connection wiring WLC112 and the 1-22 connection wiring WLC122 may be disposed between the first organic insulating layer 119 and the second organic insulating layer 121. The 1-13 connection wiring WLC113 and the 1-23 connection wiring WLC123 may be disposed between the second organic insulating layer 121 and the third organic insulating layer 123.

The second connection wiring WLC2 may extend in the second direction (e.g., the y direction and/or the −y direction) and may be electrically connected to the first island portion 11. In a plan view, the second connection wiring WLC2 may overlap the first island portion 11. The second connection wiring WLC2 may include a 2-1 connection wiring WLC21 and a 2-2 connection wiring WLC22. The 2-1 connection wiring WLC21 and the 2-2 connection wiring WLC22 may each extend in the second direction (e.g., the y direction and/or the −y direction) and may be spaced (e.g., spaced apart) from each other along the first direction (e.g., the x direction and/or the −x direction). In a plan view, the 2-1 connection wiring WLC21 and the 2-2 connection wiring WLC22 may not overlap each other. Each of the 2-1 connection wiring WLC21 and the 2-2 connection wiring WLC22 may be electrically connected to the first island portion 11.

The 2-1 connection wiring WLC21 may include a 2-11 connection wiring WLC211, a 2-12 connection wiring WLC212, and a 2-13 connection wiring WLC213, and the 2-2 connection wiring WLC22 may include a 2-21 connection wiring WLC221, a 2-22 connection wiring WLC222, and a 2-23 connection wiring WLC223. The 2-11 connection wiring WLC211, the 2-12 connection wiring WLC212, and the 2-13 connection wiring WLC213 may be disposed on different layers. The 2-11 connection wiring WLC211, the 2-12 connection wiring WLC212, and the 2-13 connection wiring WLC213 may be spaced (e.g., spaced apart) from each other along the third direction (e.g., the z direction or the −z direction). The 2-21 connection wiring WLC221, the 2-22 connection wiring WLC222, and the 2-23 connection wiring WLC223 may be disposed on different layers. The 2-21 connection wiring WLC221, the 2-22 connection wiring WLC222, and the 2-23 connection wiring WLC223 may be spaced (e.g., spaced apart) from each other along the third direction (e.g., the z direction or the −z direction).

The 2-11 connection wiring WLC211 may be disposed on (or at) the same layer as the 2-21 connection wiring WLC221, the 2-12 connection wiring WLC212 may be disposed on (or at) the same layer as the 2-22 connection wiring WLC222, and the 2-13 connection wiring WLC213 may be disposed on (or at) the same layer as the 2-23 connection wiring WLC223. For example, the 2-11 connection wiring WLC211 and the 2-21 connection wiring WLC221 may be disposed between the insulating layer OL and the first organic insulating layer 119. The 2-12 connection wiring WLC212 and the 2-22 connection wiring WLC222 may be disposed between the first organic insulating layer 119 and the second organic insulating layer 121. The 2-13 connection wiring WLC213 and the 2-23 connection wiring WLC223 may be disposed between the second organic insulating layer 121 and the third organic insulating layer 123.

For example, in one or more embodiments, the connection wiring WLC may be disposed on two or more layers by passing through at least one of the first organic insulating layer 119, the second organic insulating layer 121, or the third organic insulating layer 123. For example, the 1-11 connection wiring WLC111 may be disposed between the insulating layer OL and the first organic insulating layer 119 (as shown in FIG. 9), and in one or more embodiments, the 1-11 connection wiring WLC111 may be disposed between the first organic insulating layer 119 and the second organic insulating layer 121. Also, in one or more embodiments, the 1-11 connection wiring WLC111 disposed between the insulating layer OL and the first organic insulating layer 119, and the 1-11 connection wiring WLC111 disposed between the first organic insulating layer 119 and the second organic insulating layer 121 may be electrically connected through a contact hole formed in the first organic insulating layer 119.

However, an arrangement and a structure of the connection wiring WLC are only an example, and the connection wiring WLC may be arranged in various ways according to required design conditions.

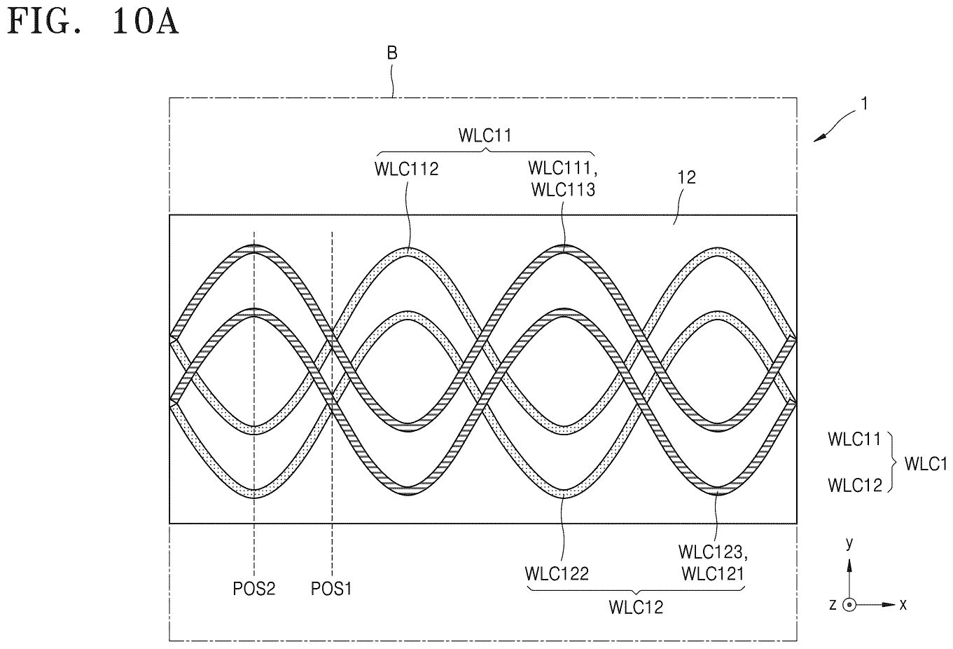

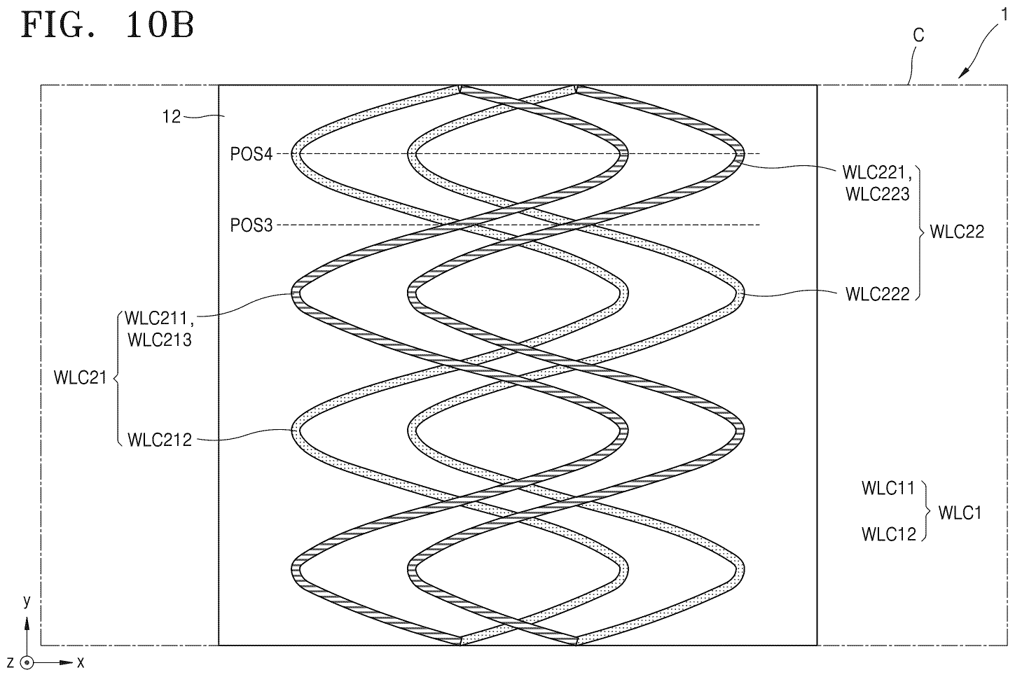

FIG. 10A is a plan view schematically illustrating a part of a display apparatus, according to one or more embodiments.

In detail, FIG. 10A may correspond to a portion B of FIG. 8.

Referring to FIG. 10A, the first connection wiring WLC1 disposed in the first bridge portion 12 may include the 1-1 connection wiring WLC11 and the 1-2 connection wiring WLC12, and at least one of the 1-1 connection wiring WLC11 or the 1-2 connection wiring WLC12 may have a curved or bent shape.

In a plan view, at least one of the 1-11 connection wiring WLC111, the 1-12 connection wiring WLC112, or the 1-13 connection wiring WLC113 may have a curved or bent shape. Also, in a plan view, at least one of the 1-21 connection wiring WLC121, the 1-22 connection wiring WLC122, or the 1-23 connection wiring WLC123 may have a curved or bent shape. For example, each of the 1-11 connection wiring WLC111, the 1-12 connection wiring WLC112, and the 1-13 connection wiring WLC113 may have a curved or bent shape. Also, each of the 1-21 connection wiring WLC121, the 1-22 connection wiring WLC122, and the 1-23 connection wiring WLC123 may have a curved or bent shape.

In a plan view, the 1-11 connection wiring WLC111 and the 1-12 connection wiring WLC112 may cross each other at a first position POS1 and may be spaced (e.g., spaced apart) from each other at a second position POS2 different from the first position POS1. The first position POS1 and the second position POS2 may be spaced (e.g., spaced apart) from each other along the first direction (e.g., the x direction and/or the −x direction). At the second position POS2, a distance between the 1-11 connection wiring WLC111 and the 1-12 connection wiring WLC112 may be the longest. In a plan view, an inflection point of each of the 1-11 connection wiring WLC111 and the 1-12 connection wiring WLC112 may be located at the second position POS2.

In a plan view, the 1-12 connection wiring WLC112 and the 1-13 connection wiring WLC113 may cross each other at the first position POS1, and may be spaced (e.g., spaced apart) from each other at the second position POS2 different from the first position POS1. At the second position POS2, a distance between the 1-12 connection wiring WLC112 and the 1-13 connection wiring WLC113 may be the longest. In a plan view, an inflection point of each of the 1-12 connection wiring WLC112 and the 1-13 connection wiring WLC113 may be located at the second position POS2.

Although the 1-11 connection wiring WLC111 and the 1-13 connection wiring WLC113 completely overlap each other in a plan view in FIG. 10A, this is only an example, and the 1-11 connection wiring WLC111 and the 1-13 connection wiring WLC113 may be spaced (e.g., spaced apart) from each other in a plan view.

In a plan view, at least one of the 1-21 connection wiring WLC121, the 1-22 connection wiring WLC122, or the 1-23 connection wiring WLC123 may have a curved or bent shape. For example, each of the 1-21 connection wiring WLC121, the 1-22 connection wiring WLC122, and the 1-23 connection wiring WLC123 may have a curved or bent shape.

In a plan view, the 1-21 connection wiring WLC121 and the 1-22 connection wiring WLC122 may cross each other at the first position POS1, and may be spaced (e.g., spaced apart) from each other at the second position POS2 different from the first position POS1. At the second position POS2, a distance between the 1-21 connection wiring WLC121 and the 1-22 connection wiring WLC122 may be the longest. In a plan view, an inflection point of each of the 1-21 connection wiring WLC121 and the 1-22 connection wiring WLC122 may be located at the second position POS2.

In a plan view, the 1-22 connection wiring WLC122 and the 1-23 connection wiring WLC123 may cross each other at the first position POS1, and may be spaced (e.g., spaced apart) from each other at the second position POS2 different from the first position POS1. At the second position POS2, a distance between the 1-22 connection wiring WLC122 and the 1-23 connection wiring WLC123 may be the longest. In a plan view, an inflection point of each of the 1-22 connection wiring WLC122 and the 1-23 connection wiring WLC123 may be located at the second position POS2.

Although the 1-21 connection wiring WLC121 and the 1-23 connection wiring WLC123 completely overlap each other in a plan view in FIG. 10A, this is only an example, and the 1-21 connection wiring WLC121 and the 1-23 connection wiring WLC123 may be spaced (e.g., spaced apart) from each other in a plan view.

For example, the curved or bent shape may include a serpentine shape. For example, the curved or bent shape may include a sine wave shape. However, this is only an example, and the curved or bent shape may include any of various shapes excluding a linear shape.

FIG. 10B is a plan view schematically illustrating a part of a display apparatus, according to one or more embodiments.

In detail, FIG. 10B may correspond to a portion C of FIG. 8.

Referring to FIG. 10B, the second connection wiring WLC2 disposed in the first bridge portion 12 may include the 2-1 connection wiring WLC21 and the 2-2 connection wiring WLC22, and at least one of the 2-1 connection wiring WLC21 or the 2-2 connection wiring WLC22 may have a curved or bent shape.

In a plan view, at least one of the 2-11 connection wiring WLC211, the 2-12 connection wiring WLC212, or the 2-13 connection wiring WLC213 may have a curved or bent shape. Also, in a plan view, at least one of the 2-21 connection wiring WLC221, the 2-22 connection wiring WLC222, or the 2-23 connection wiring WLC223 may have a curved or bent shape. For example, each of the 2-11 connection wiring WLC211, the 2-12 connection wiring WLC212, and the 2-13 connection wiring WLC213 may have a curved or bent shape. Also, each of the 2-21 connection wiring WLC221, the 2-22 connection wiring WLC222, and the 2-23 connection wiring WLC223 may have a curved or bent shape.

In a plan view, the 2-11 connection wiring WLC211 and the 2-12 connection wiring WLC212 may cross each other at a third position POS3, and may be spaced (e.g., spaced apart) from each other at a fourth position POS4 different from the third position POS3. The third position POS3 and the fourth position POS4 may be spaced (e.g., spaced apart) from each other along the second direction (e.g., the y direction and/or the −y direction). At the fourth position POS4, a distance between the 2-11 connection wiring WLC211 and the 2-12 connection wiring WLC212 may be the longest. In a plan view, an inflection point of each of the 2-11 connection wiring WLC211 and the 2-12 connection wiring WLC212 may be located at the fourth position POS4.

In a plan view, the 2-12 connection wiring WLC212 and the 2-13 connection wiring WLC213 may cross each other at the third position POS3, and may be spaced (e.g., spaced apart) from each other at the fourth position POS4 different from the third position POS3. At the fourth position POS4, a distance between the 2-12 connection wiring WLC212 and the 2-13 connection wiring WLC213 may be the longest. In a plan view, an inflection point of each of the 2-12 connection wiring WLC212 and the 2-13 connection wiring WLC213 may be located at the fourth position POS4.

Although the 2-11 connection wiring WLC211 and the 2-13 connection wiring WLC213 completely overlap each other in a plan view in FIG. 10B, this is only an example, and the 2-11 connection wiring WLC211 and the 2-13 connection wiring WLC213 may be spaced (e.g., spaced apart) from each other in a plan view.

In a plan view, at least one of the 2-21 connection wiring WLC221, the 2-22 connection wiring WLC222, or the 2-23 connection wiring WLC223 may have a curved or bent shape. For example, each of the 2-21 connection wiring WLC221, the 2-22 connection wiring WLC222, and the 2-23 connection wiring WLC223 may have a curved or bent shape.

In a plan view, the 2-21 connection wiring WLC221 and the 2-22 connection wiring WLC222 may cross each other at the third position POS3, and may be spaced (e.g., spaced apart) from each other at the fourth position POS4 different from the third position POS3. At the fourth position POS, a distance between the 2-21 connection wiring WLC221 and the 2-22 connection wiring WLC222 may be the longest. In a plan view, an inflection point of each of the 2-21 connection wiring WLC221 and the 2-22 connection wiring WLC222 may be located at the fourth position POS4.

In a plan view, the 2-22 connection wiring WLC222 and the 2-23 connection wiring WLC223 may cross each other at the third position POS3, and may be spaced (e.g., spaced apart) from each other at the fourth position POS4 different from the third position POS3. At the fourth position POS4, a distance between the 2-22 connection wiring WLC222 and the 2-23 connection wiring WLC223 may be the longest. In a plan view, an inflection point of each of the 2-22 connection wiring WLC222 and the 2-23 connection wiring WLC223 may be located at the fourth position POS4.

Although the 2-21 connection wiring WLC221 and the 2-23 connection wiring WLC223 completely overlap each other in a plan view in FIG. 10B, this is only an example, the 2-21 connection wiring WLC221 and the 2-23 connection wiring WLC223 may be spaced (e.g., spaced apart) from each other in a plan view.

For example, the curved or bent shape may include a serpentine shape. For example, the curved or bent shape may include a sine wave shape. However, this is only an example, and the curved or bent shape may include one or more of various shapes excluding a linear shape.

As shown in FIGS. 10A and 10B, the first connection wiring WLC1 and the second connection wiring WLC2 may have sine wave shapes with two wavelengths.

However, this is only an example, and the first connection wiring WLC1 and the second connection wiring WLC2 may have sine wave shapes with three wavelengths or sine wave shapes with four or more wavelengths. Shapes and lengths of the first connection wiring WLC1 and the second connection wiring WLC2 may vary according to required design conditions.

Because the first connection wiring WLC1 and the second connection wiring WLC2 have a curved or bent shape, stress applied to the first connection wiring WLC1 and the second connection wiring WLC2 when the display apparatus 1 is stretched may be reduced. Accordingly, the durability of the display apparatus 1 may be improved. Also, an elongation rate of the display apparatus 1 may be increased.

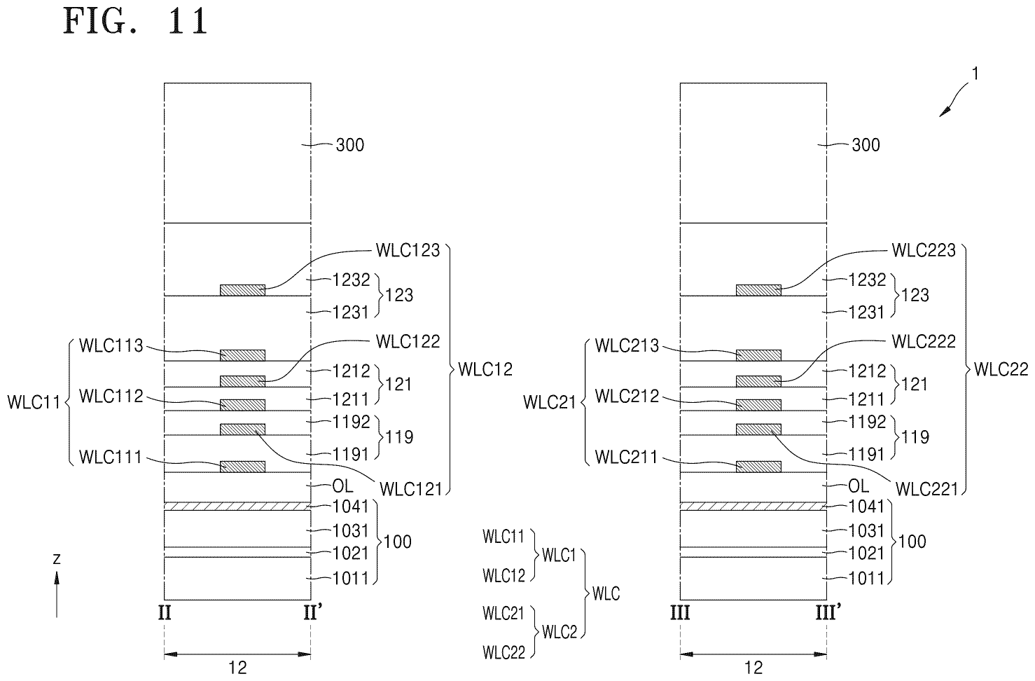

FIG. 11 is a cross-sectional view schematically illustrating a display apparatus, according to one or more embodiments.

In detail, FIG. 11 is a cross-sectional view taken along the lines II-II′ and III-III′ of FIG. 8.

The substrate 100 corresponding to the first bridge portion 12 may have the same stacked structure as the substrate 100 corresponding to the first island portion 11. In one or more embodiments, the substrate 100 corresponding to the first bridge portion 12 may include the first base layer 1011, the first barrier layer 1021, the second base layer 1031, and the second barrier layer 1041.

The insulating layer OL, the first organic insulating layer 119, the second organic insulating layer 121, and the third organic insulating layer 123 may be disposed on the substrate 100. The encapsulation layer 300 may be disposed on the third organic insulating layer 123.

The first organic insulating layer 119 may include a 1-1 organic insulating layer 1191 and a 1-2 organic insulating layer 1192. The second organic insulating layer 121 may include a 2-1 organic insulating layer 1211 and a 2-2 organic insulating layer 1212. The third organic insulating layer 123 may include a 3-1 organic insulating layer 1231 and a 3-2 organic insulating layer 1232. In this structure, the 1-2 organic insulating layer 1192 may be disposed on the 1-1 organic insulating layer 1191, the 2-1 organic insulating layer 1211 may be disposed on the 1-2 organic insulating layer 1192, the 2-2 organic insulating layer 1212 may be disposed on the 2-1 organic insulating layer 1211, the 3-1 organic insulating layer 1231 may be disposed on the 2-2 organic insulating layer 1212, and the 3-2 organic insulating layer 1232 may be disposed on the 3-1 organic insulating layer 1231.

The connection wiring WLC may include a first connection wiring WLC1 and a second connection wiring WLC2. The first connection wiring WLC1 may include the 1-1 connection wiring WLC11 and the 1-2 connection wiring WLC12. In a plan view, the 1-1 connection wiring WLC11 and the 1-2 connection wiring WLC12 may overlap each other.

The 1-1 connection wiring WLC11 may include the 1-11 connection wiring WLC111, the 1-12 connection wiring WLC112, and the 1-13 connection wiring WLC113, and the 1-2 connection wiring WLC12 may include the 1-21 connection wiring WLC121, the 1-22 connection wiring WLC122, and the 1-23 connection wiring WLC123.

The 1-11 connection wiring WLC111, the 1-12 connection wiring WLC112, and the 1-13 connection wiring WLC113 may be disposed on different layers. The 1-11 connection wiring WLC111, the 1-12 connection wiring WLC112, and the 1-13 connection wiring WLC113 may be spaced (e.g., spaced apart) from each other along the third direction (e.g., the z direction or the −z direction). The 1-21 connection wiring WLC121, the 1-22 connection wiring WLC122, and the 1-23 connection wiring WLC123 may be disposed on different layers. The 1-21 connection wiring WLC121, the 1-22 connection wiring WLC122, and the 1-23 connection wiring WLC123 may be spaced (e.g., spaced apart) from each other along the third direction (e.g., the z direction or the −z direction).

The 1-1 connection wiring WLC11 and the 1-2 connection wiring WLC12 may be disposed on different layers. The 1-11 connection wiring WLC111, the 1-12 connection wiring WLC112, the 1-13 connection wiring WLC113, the 1-21 connection wiring WLC121, the 1-22 connection wiring WLC122, and the 1-23 connection wiring WLC123 may overlap each other in a plan view (and in a cross sectional view), but may be disposed on different layers. The 1-11 connection wiring WLC111, the 1-21 connection wiring WLC121, the 1-12 connection wiring WLC112, the 1-22 connection wiring WLC122, the 1-13 connection wiring WLC113, and the 1-23 connection wiring WLC123 may be sequentially spaced (e.g., spaced apart) from each other along the third direction (e.g., the z direction or the −z direction).

For example, the 1-11 connection wiring WLC111 may be disposed between the insulating layer OL and the 1-1 organic insulating layer 1191. The 1-21 connection wiring WLC121 may be disposed between the 1-1 organic insulating layer 1191 and the 1-2 organic insulating layer 1192. The 1-12 connection wiring WLC112 may be disposed between the 1-2 organic insulating layer 1192 and the 2-1 organic insulating layer 1211. The 1-22 connection wiring WLC122 may be disposed between the 2-1 organic insulating layer 1211 and the 2-2 organic insulating layer 1212. The 1-13 connection wiring WLC113 may be disposed between the 2-2 organic insulating layer 1212 and the 3-1 organic insulating layer 1231. The 1-23 connection wiring WLC123 may be disposed between the 3-1 organic insulating layer 1231 and the 3-2 organic insulating layer 1232.

The second connection wiring WLC2 may include the 2-1 connection wiring WLC21 and the 2-2 connection wiring WLC22. In a plan view, the 2-1 connection wiring WLC21 and the 2-2 connection wiring WLC22 may overlap each other.

The 2-1 connection wiring WLC21 may include the 2-11 connection wiring WLC211, the 2-12 connection wiring WLC212, and the 2-13 connection wiring WLC213, and the 2-2 connection wiring WLC22 may include the 2-21 connection wiring WLC221, the 2-22 connection wiring WLC222, and the 2-23 connection wiring WLC223.

The 2-11 connection wiring WLC211, the 2-12 connection wiring WLC212, and the 2-13 connection wiring WLC213 may be disposed on different layers. The 2-11 connection wiring WLC211, the 2-12 connection wiring WLC212, and the 2-13 connection wiring WLC213 may be spaced(e.g., spaced apart) from each other along the third direction (e.g., the z direction or the −z direction). The 2-21 connection wiring WLC221, the 2-22 connection wiring WLC222, and the 2-23 connection wiring WLC223 may be disposed on different layers. The 2-21 connection wiring WLC221, the 2-22 connection wiring WLC222, and the 2-23 connection wiring WLC223 may be spaced (e.g., spaced apart) from each other along the third direction (e.g., the z direction or the −z direction).

The 2-1 connection wiring WLC21 and the 2-2 connection wiring WLC22 may be disposed on different layers. The 2-11 connection wiring WLC211, the 2-12 connection wiring WLC212, the 2-13 connection wiring WLC213, the 2-21 connection wiring WLC221, the 2-22 connection wiring WLC222, and the 2-23 connection wiring WLC223 may overlap each other in a plan view (and in a cross sectional view), but may be disposed on different layers. The 2-11 connection wiring WLC211, the 2-21 connection wiring WLC221, the 2-12 connection wiring WLC212, the 2-22 connection wiring WLC222, the 2-13 connection wiring WLC213, and the 2-23 connection wiring WLC223 may be sequentially spaced (e.g., spaced apart) from each other along the third direction (e.g., the z direction or the −z direction).

For example, the 2-11 connection wiring WLC211 may be disposed between the insulating layer OL and the 1-1 organic insulating layer 1191. The 2-21 connection wiring WLC221 may be disposed between the 1-1 organic insulating layer 1191 and the 1-2 organic insulating layer 1192. The 2-12 connection wiring WLC212 may be disposed between the 1-2 organic insulating layer 1192 and the 2-1 organic insulating layer 1211. The 2-22 connection wiring WLC222 may be disposed between the 2-1 organic insulating layer 1211 and the 2-2 organic insulating layer 1212. The 2-13 connection wiring WLC213 may be disposed between the 2-2 organic insulating layer 1212 and the 3-1 organic insulating layer 1231. The 2-23 connection wiring WLC223 may be disposed between the 3-1 organic insulating layer 1231 and the 3-2 organic insulating layer 1232.

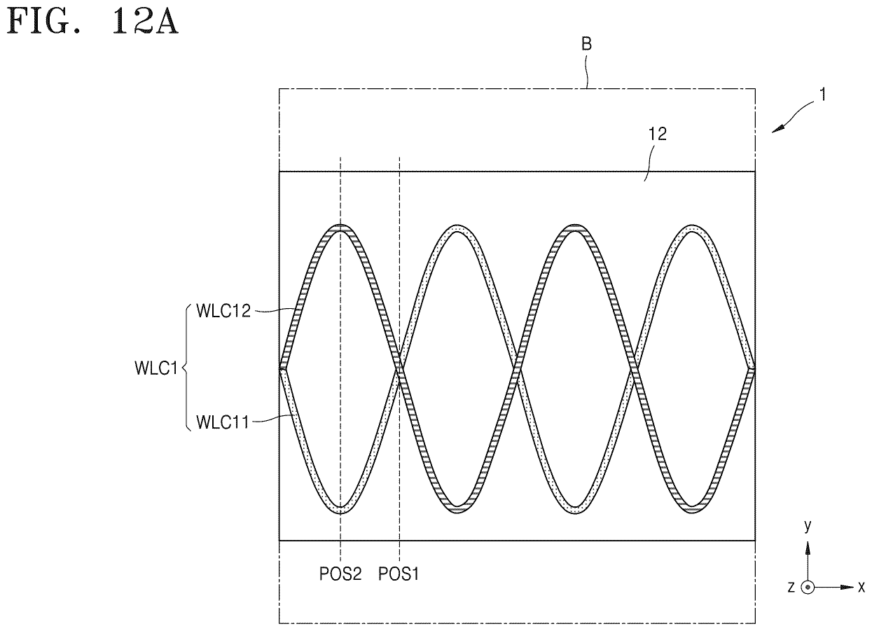

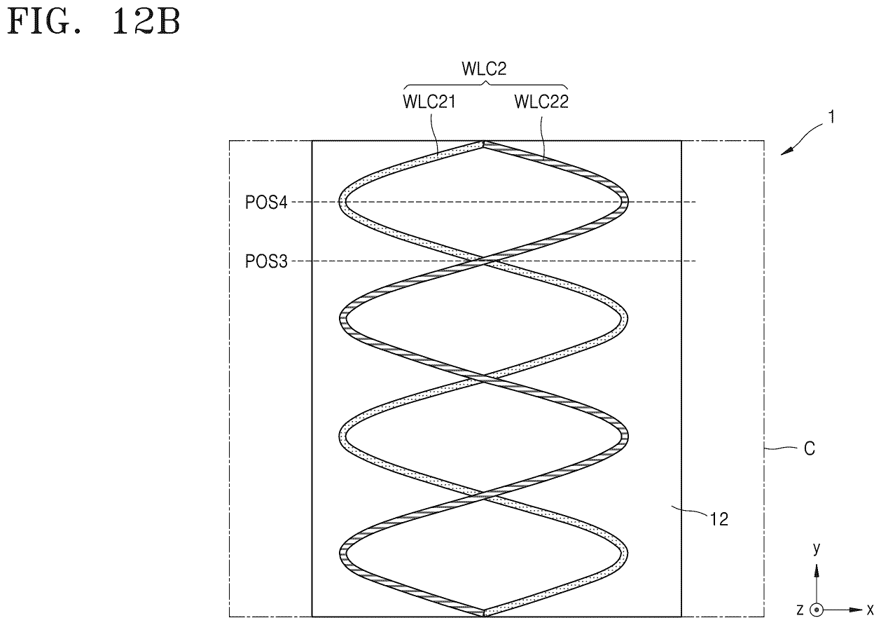

FIG. 12A is a plan view schematically illustrating a part of a display apparatus, according to one or more embodiments.

In detail, FIG. 12A may correspond to the portion B of FIG. 8.

Referring to FIG. 12A, the first connection wiring WLC1 disposed in the first bridge portion 12 may include the 1-1 connection wiring WLC11 and the 1-2 connection wiring WLC12.

At least one of the 1-1 connection wiring WLC11 or the 1-2 connection wiring WLC12 may have a curved or bent shape. For example, each of the 1-1 connection wiring WLC11 and the 1-2 connection wiring WLC12 may have a curved or bent shape.

In a plan view, the 1-1 connection wiring WLC11 and the 1-2 connection wiring WLC12 may cross each other at the first position POS1, and may be spaced (e.g., spaced apart) from each other at the second position POS2 different from the first position POS1. The first position POS1 and the second position POS2 may be spaced (e.g., spaced apart) from each other along the first direction (e.g., the x direction and/or the −x direction). At the second position POS2, a distance between the 1-1 connection wiring WLC11 and the 1-2 connection wiring WLC12 may be the longest. In a plan view, an inflection point of each of the 1-1 connection wiring WLC11 and the 1-2 connection wiring WLC12 may be located at the second position POS2.

Although the 1-11 connection wiring WLC111, the 1-12 connection wiring WLC112, and the 1-13 connection wiring WLC113 completely overlap each other in a plan view in FIG. 12A, this is only an example, and the 1-11 connection wiring WLC111, the 1-12 connection wiring WLC112, and the 1-13 connection wiring WLC113 may be spaced (e.g., spaced apart) from each other in a plan view.

Although the 1-21 connection wiring WLC121, the 1-22 connection wiring WLC122, and the 1-23 connection wiring WLC123 completely overlap each other in a plan view in FIG. 12A, this is only an example, and the 1-21 connection wiring WLC121, the 1-22 connection wiring WLC122, and the 1-23 connection wiring WLC123 may be spaced (e.g., spaced apart) from each other in a plan view.

For example, the curved or bent shape may include a serpentine shape. For example, the curved or bent shape may include a sine wave shape. However, this is only an example, and the curved or bent shape may include any of various shapes excluding a linear shape.

FIG. 12B is a plan view schematically illustrating a part of a display apparatus, according to one or more embodiments.

In detail, FIG. 12B may correspond to the portion C of FIG. 8.

Referring to FIG. 12B, the second connection wiring WLC2 disposed in the first bridge portion 12 may include the 2-1 connection wiring WLC21 and the 2-2 connection wiring WLC22.

At least one of the 2-1 connection wiring WLC21 or the 2-2 connection wiring WLC22 may have a curved or bent shape. For example, each of the 2-1 connection wiring WLC21 and the 2-2 connection wiring WLC22 may have a curved or bent shape.

In a plan view, the 2-1 connection wiring WLC21 and the 2-2 connection wiring WLC22 may cross each other at the third position POS3, and may be spaced (e.g., spaced apart) from each other at the fourth position POS4 different from the third position POS3. The third position POS3 and the fourth position POS4 may be spaced (e.g., spaced apart) from each other along the second direction (e.g., the y direction and/or the −y direction). At the fourth position POS4, a distance between the 2-1 connection wiring WLC21 and the 2-2 connection wiring WLC22 may be the longest. In a plan view, an inflection point of each of the 2-1 connection wiring WLC21 and the 2-2 connection wiring WLC22 may be located at the fourth position POS4.

Although the 2-11 connection wiring WLC211 (see FIG. 11), the 2-12 connection wiring WLC212 (see FIG. 11), and the 2-13 connection wiring WLC213 (see FIG. 11) completely overlap each other in a plan view in FIG. 12B, this is only an example, and the 2-11 connection wiring WLC211 (see FIG. 11), the 2-12 connection wiring WLC212 (see FIG. 11), and the 2-13 connection wiring WLC213 (see FIG. 11) may be spaced (e.g., spaced apart) from each other in a plan view.

Although the 2-21 connection wiring WLC221 (see FIG. 11), the 2-22 connection wiring WLC222 (see FIG. 11), and the 2-23 connection wiring WLC223 (see FIG. 11) completely overlap each other in a plan view in FIG. 12B, this is only an example, and the 2-21 connection wiring WLC221 (see FIG. 11), the 2-22 connection wiring WLC222 (see FIG. 11), and the 2-23 connection wiring WLC223 (see FIG. 11) may be spaced (e.g., spaced apart) from each other in a plan view.

For example, the curved or bent shape may include a serpentine shape. For example, the curved or bent shape may include a sine wave shape. However, this is only an example, and the curved or bent shape may include any of various shapes excluding a linear shape.

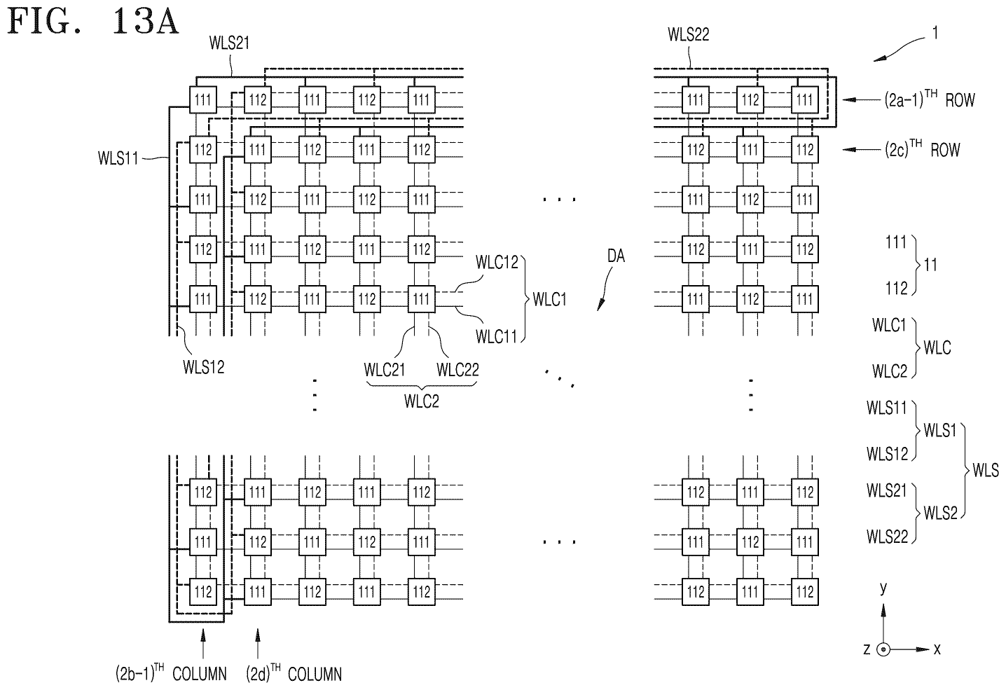

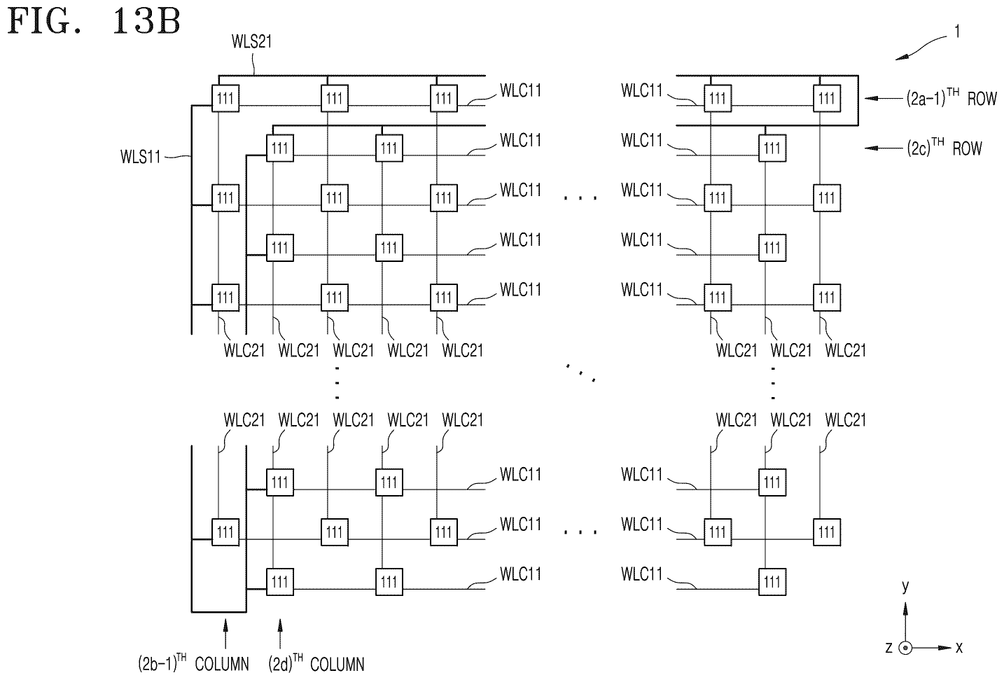

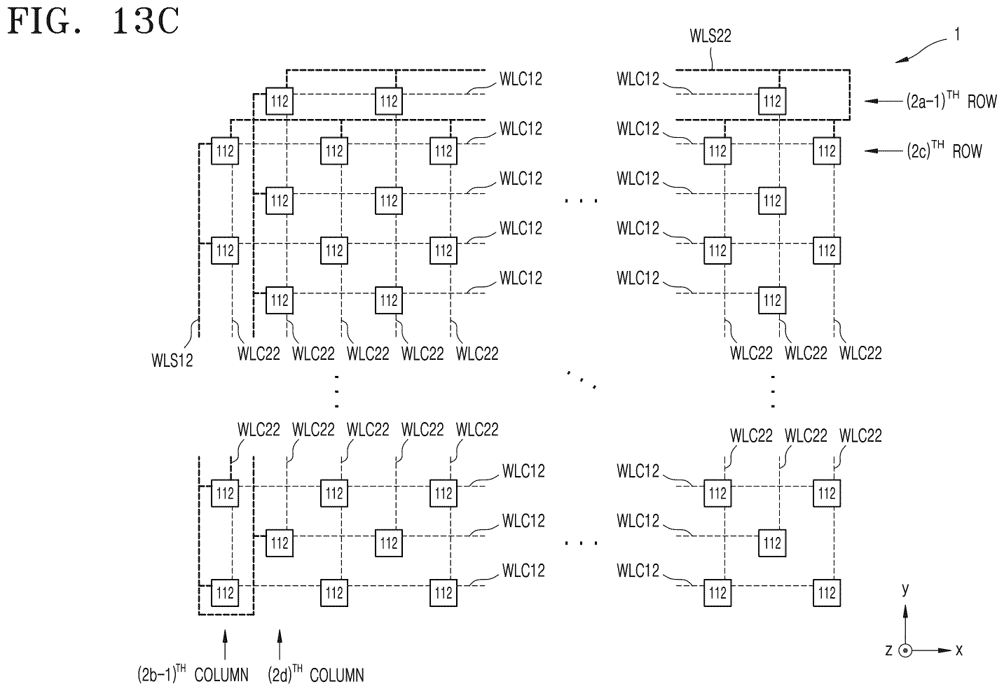

FIGS. 13A-13C are plan views schematically illustrating a part of a display apparatus, according to one or more embodiments.

In detail, FIG. 13B is a plan view illustrating only the 11^{th} island portion 111, the 1-1 connection wiring WLC11, and the 2-1 connection wiring WLC21, and FIG. 13C is a plan view illustrating only the 12th island portion 112, the 1-2 connection wiring WLC12, and the 2-2 connection wiring WLC22.

Referring to FIGS. 13A-13C, the first island portion 11 may include the 11^{th} island portion 111 and the 12^{th} island portion 112.

A plurality of 11^{th} island portions 111 and a plurality of 12^{th} island portions 112 may be provided in the display area DA. The plurality of 11^{th} island portions 111 may be spaced (e.g., spaced apart) from each other along the first direction (e.g., the x direction and/or the −x direction) and the second direction (e.g., the y direction and/or the −y direction). The plurality of 12^{th} island portions 112 may be spaced (e.g., spaced apart) from each other along the first direction (e.g., the x direction and/or the −x direction) and the second direction (e.g., the y direction and/or the −y direction). The plurality of 11^{th} island portions 111 and the plurality of 12^{th} island portions 112 may be alternately arranged to be spaced (e.g., spaced apart) from each other along the first direction (e.g., the x direction and/or the −x direction) and the second direction (e.g., the y direction and/or the −y direction). The 11^{th} island portion 111 and the 12^{th} island portion 112 may be alternately arranged along the first direction (e.g., the x direction and/or the −x direction). The 11^{th} island portion 111 and the 12^{th} island portion 112 may be alternately arranged along the second direction (e.g., the y direction and/or the −y direction).

The plurality of 11^{th} island portions 111 and the plurality of 12^{th} island portions 112 may be arranged in a lattice shape. The plurality of 11^{th} island portions 111 and the plurality of 12^{th} island portions 112 may be arranged in a plurality of rows and columns.

The plurality of 11^{th} island portions 111 may be located at a position of ‘(2a-1)^{th} row (2b-1)^{th} column’ or a position of ‘(2c)^{th} row (2d)^{th} column’ (a, b, c, and d are positive numbers greater than 0). That is, the plurality of 11^{th} island portions 111 may be located at a position of ‘odd-numbered row odd-numbered column’ or a position of ‘even-numbered row even-numbered column’.

For example, the plurality of 11^{th} island portions 111 may be located at a position of ‘1^{st} row 1^{st} column’, a position of ‘1^{st} row 3^{rd} column’, a position of ‘3^{rd} row 1^{st} column’, a position of ‘3^{rd} row 3^{rd} column’, etc. Also, the plurality of 11^{th} island portions 111 may be located at a position of ‘2^{nd} row 2^{nd} column’, a position of ‘2^{nd} row 4^{th} column’, a position of ‘4^{th} row 2^{nd} column’, a position of ‘4^{th} row 4^{th} column’, etc.

The plurality of 12^{th} island portions 112 may be located at a position of ‘(2a-1)^{th} row (2d)^{th} column’ or a position of ‘(2c)^{th} row (2b-1)^{th} column’. That is, the plurality of 12^{th} island portions 112 may be located at a position of ‘odd-numbered row even-numbered column’ or a position of ‘even-numbered row odd-numbered column’.

For example, the plurality of 12^{th} island portions 112 may be located at a position of ‘1^{st} row 2^{nd} column’, a position of ‘1^{st} row 4^{th} column’, a position of ‘3^{rd} row 2^{nd} column’, a position of ‘3^{rd} row 4^{th} column’, etc. Also, the plurality of 12^{th} island portions 112 may be located at a position of ‘2^{nd} row 1^{st} column’, a position of ‘2^{nd} row 3^{rd} column’, a position of ‘4^{th} row 1^{st} column’, a position of ‘4^{th} row 3^{rd} column’, etc.

The connection wiring WLC may include the first connection wiring WLC1 and the second connection wiring WLC2. The first connection wiring WLC1 may extend in the first direction (e.g., the x direction and/or the −x direction) to overlap a plurality of 11^{th} island portions 111 and a plurality of 12^{th} island portions 112 arranged along the first direction (e.g., the x direction and/or the −x direction) in a plan view. The first connection wiring WLC1 may overlap the 11^{th} island portions 111 and the 12^{th} island portions 112 arranged in the same row. A plurality of first connection wirings WLC1 may be provided. The plurality of first connection wirings WLC1 may be spaced (e.g., spaced apart) from each other along the second direction (e.g., the y direction and/or the −y direction). For example, the plurality of first connection wirings WLC1 may overlap the 11^{th} island portions 111 and the 12^{th} island portions 112 located in positions such as ‘1^{st} row’, ‘2^{nd} row’, and ‘3^{rd} row’.

The second connection wiring WLC2 may extend in the second direction (e.g., the y direction and/or the −y direction) to overlap a plurality of 11^{th} island portions 111 and a plurality of 12^{th} island portions 112 arranged along the second direction (e.g., the y direction and/or the −y direction) in a plan view. The second connection wiring WLC2 may overlap the 11^{th} island portions 111 and the 12^{th} island portions 112 disposed in the same column. A plurality of second connection wirings WLC2 may be provided. The plurality of second connection wirings WLC2 may be spaced (e.g., spaced apart) from each other along the first direction (e.g., the x direction and/or the −x direction). For example, the second connection wiring WLC2 may overlap the 11^{th} island portions 111 and the 12^{th} island portions 112 located in positions such as ‘1^{st} column’, ‘2^{nd} column’, and ‘3^{rd} column’.

The first connection wiring WLC1 may include the 1-1 connection wiring WLC11 and the 1-2 connection wiring WLC12. Each of the plurality of first connection wirings WLC1 may include the 1-1 connection wiring WLC11 and the 1-2 connection wiring WLC12. Also, the second connection wiring WLC2 may include the 2-1connection wiring WLC21 and the 2-2 connection wiring WLC22. Each of the plurality of second connection wirings WLC2 may include the 2-1 connection wiring WLC21 and the 2-2 connection wiring WLC22.

As shown in FIG. 13B, the 1-1 connection wiring WLC11 may be electrically connected to a plurality of 11^{th} island portions 111. That is, the 1-1 connection wiring WLC11 may contact transistors of the plurality of 11^{th} island portions 111. In detail, each of a plurality of 1-1 connection wirings WLC11 may be electrically connected to a plurality of 11^{th} island portions 111 disposed along the first direction (e.g., the x direction and/or the −x direction). Each of the plurality of 1-1 connection wirings WLC11 may be electrically connected to the 11^{th} island portions 111 disposed in the same row.

For example, one of the plurality of 1-1 connection wirings WLC11 may be electrically connected to a plurality of 11^{th} island portions 111 located in a position of ‘1^{st} row’. Also, another one of the plurality of 1-1 connection wirings WLC11 may be electrically connected to a plurality of 11^{th} island portions 111 located in a position of ‘2^{nd} row’.

The 1-1 connection wiring WLC11 may not be electrically connected to the 12^{th} island portion 112. In a plan view, the 1-1 connection wiring WLC11 may overlap the 12^{th} island portion 112, but, in a cross-sectional view, the 1-1 connection wiring WLC11 may be spaced (e.g., spaced apart) from a transistor of the 12^{th} island portion 112. That is, the 1-1 connection wiring WLC11 may pass through the 12^{th} island portion 112 without contacting the transistor of the 12^{th} island portion 112.

As shown in FIG. 13B, the 2-1 connection wiring WLC21 may be electrically connected to a plurality of 11^{th} island portions 111. That is, the 2-1 connection wiring WLC21 may contact transistors of the plurality of 11^{th} island portions 111. In detail, each of a plurality of 2-1 connection wirings WLC21 may be electrically connected to a plurality of 11^{th} island portions 111 disposed along the second direction (e.g., the y direction and/or the −y direction). Each of the plurality of 2-1 connection wirings WLC21 may be electrically connected to the 11^{th} island portions 111 disposed in the same column.

For example, one of the plurality of 2-1 connection wirings WLC21 may be electrically connected to a plurality of 11^{th} island portions 111 located in a position of ‘1^{st} column’. Also, another one of the plurality of 2-1 connection wirings WLC21 may be electrically connected to a plurality of 11^{th} island portions 111 located in a position of ‘2^{nd} column’.

The 2-1 connection wiring WLC21 may not be electrically connected to the 12^{th} island portion 112. In a plan view, the 2-1 connection wiring WLC21 may overlap the 12^{th} island portion 112, but in a cross-sectional view, the 2-1 connection wiring WLC21 may be spaced (e.g., spaced apart) from a transistor of the 12^{th} island portion 112. That is, the 2-1 connection wiring WLC21 may pass through the 12^{th} island portion 112 without contacting the transistor of the 12^{th} island portion 112.

As shown in FIG. 13C, the 1-2 connection wiring WLC12 may be electrically connected to a plurality of 12^{th} island portions 112. The 1-2 connection wiring WLC12 may contact transistors of the plurality of 12^{th} island portions 112. In detail, each of a plurality of 1-2 connection wirings WLC12 may be electrically connected to a plurality of 12^{th} island portions 112 disposed along the first direction (e.g., the x direction and/or the −x direction). Each of the plurality of 1-2 connection wirings WLC12 may be electrically connected to the 12^{th} island portions disposed in the same row.

For example, one of the plurality of 1-2 connection wirings WLC12 may be electrically connected to a plurality of 12^{th} island portions 112 located in a position of ‘1^{st} row’. Also, another one of the plurality of 1-2 connection wirings WLC12 may be electrically connected to a plurality of 12^{th} island portions 112 located in a position of ‘2^{nd} row’.

The 1-2 connection wiring WLC12 may not be electrically connected to the 11^{th} island portion 111. In a plan view, the 1-2 connection wiring WLC12 may overlap the 11^{th} island portion 111, but in a cross-sectional view, the 1-2 connection wiring WLC12 may be spaced (e.g., spaced apart) from a transistor of the 11^{th} island portion 111. That is, the 1-2 connection wiring WLC12 may pass through the 11^{th} island portion 111 without contacting the transistor of the 11^{th} island portion 111.

As shown in FIG. 13C, the 2-2 connection wiring WLC22 may be electrically connected to a plurality of 12^{th} island portions 112. That is, the 2-2 connection wiring WLC22 may contact transistors of the plurality of 12^{th} island portions 112. In detail, each of a plurality of 2-2 connection wirings WLC22 may be electrically connected to a plurality of 12^{th} island portions 112 disposed along the second direction (e.g., the y direction and/or the −y direction). Each of the plurality of 2-2 connection wirings WLC22 may be electrically connected to the 12^{th} island portions 112 disposed in the same column.

For example, any one of the plurality of 2-2 connection wirings WLC22 may be electrically connected to a plurality of 12^{th} island portions 112 located in a position of ‘1^{st} column’. Also, another one of the plurality of 2-2 connection wirings WLC22 may be electrically connected to a plurality of 12^{th} island portions 112 located in a position of ‘2^{nd} column’.

The 2-2 connection wiring WLC22 may not be electrically connected to the 11^{th} island portion 111. In a plan view, the 2-2 connection wiring WLC22 may overlap the 11^{th} island portion 111, but in a cross-sectional view, the 2-2 connection wiring WLC22 may be spaced (e.g., spaced apart) from a transistor of the 11^{th} island portion 111. That is, the 2-2 connection wiring WLC22 may pass through the 11^{th} island portion 111 without contacting the transistor of the 11^{th} island portion 111.

Referring to FIGS. 9, and 13A-13C, at least one of the first connection wiring WLC1 or the second connection wiring WLC2 may include at least one of a voltage line or a signal line.

Each of the 1-11 connection wiring WLC111, the 1-12 connection wiring WLC112, and the 1-13 connection wiring WLC113 of the 1-1 connection wiring WLC11 may include at least one of a voltage line or a signal line. Each of the 1-21 connection wiring WLC121, the 1-22 connection wiring WLC122, and the 1-23 connection wiring WLC123 of the 1-2 connection wiring WLC12 may include at least one of a voltage line or a signal line. Each of the 2-11 connection wiring WLC211, the 2-12 connection wiring WLC212, and the 2-13 connection wiring WLC213 of the 2-1 connection wiring WLC21 may include at least one of a voltage line or a signal line. Each of the 2-21 connection wiring WLC221, the 2-22 connection wiring WLC222, and the 2-23 connection wiring WLC223 of the 2-2 connection wiring may include at least one of a voltage line or a signal line.

For example, the voltage line may be the driving voltage line VDDL and/or the common voltage line VSSL described with reference to FIG. 6A. Also, the signal line may be the scan line SL and/or the data line DL described with reference to FIG. 6A.

For example, the voltage line may be the driving voltage line VDDL, the common voltage line VSSL, the first initialization voltage line VIL1, and/or the second initialization voltage line VIL2 described with reference to FIG. 6B. Also, the signal line may be the first scan line SL1, the second scan line SL2, the third scan line SL3, the emission control line EML, and/or the data line DL described with reference to FIG. 6B.

For example, the voltage line may be the driving voltage line VDDL, the common voltage line VSSL, the first initialization voltage line VIL1, the second initialization voltage line VIL2, and/or the sustain voltage line VSL described with reference to FIG. 6C. Also, the signal line may be the first scan line SL1, the second scan line SL2, the third scan line SL3, the emission control line EML, and/or the data line DL described with reference to FIG. 6C.

However, the types of the voltage line and the signal line described above are only examples, and may vary according to a configuration of the pixel circuit PC (see FIG. 5).

The 1-11 connection wiring WLC111 and the 1-21 connection wiring WLC121 may be the same type of voltage line or the same type of signal line. For example, each of the 1-11 connection wiring WLC111 and the 1-21 connection wiring WLC121 may be the driving voltage line VDDL (see FIG. 6A). Likewise, the 1-12 connection wiring WLC112 and the 1-22 connection wiring WLC122 may be the same type of voltage line or the same type of signal line. The 1-13 connection wiring WLC113 and the 1-23 connection wiring WLC123 may be the same type of voltage line or the same type of signal line. The 2-11 connection wiring WLC211 and the 2-21 connection wiring WLC221 may be the same type of voltage line or the same type of signal line. The 2-12 connection wiring WLC212 and the 2-22 connection wiring WLC222 may be the same type of voltage line or the same type of signal line. The 2-13 connection wiring WLC213 and the 2-23 connection wiring WLC223 may be the same type of voltage line or the same type of signal line.

However, this is only an example, and an arrangement of the connection wiring WLC is not limited thereto. Unlike in FIG. 9, the same type of signal line and voltage line may not be disposed on (or at) the same layer. For example, a 1-11 wiring may be the driving voltage line VDDL (see FIG. 6A), and a 2-21 wiring may be the scan line SL (see FIG. 6A).

A power supply wiring WLS may supply power to the first island portion 11. The power supply wiring WLS may include a first power supply wiring WLS1 and a second power supply wiring WLS2. The first power supply wiring WLS1 may supply a first power supply voltage to a plurality of 11^{th} island portions 111 and a plurality of 12^{th} island portions 112 arranged along the first direction (e.g., the x direction and/or the −x direction) in a plan view. The second power supply wiring WLS2 may supply a second power supply voltage to a plurality of 11^{th} island portions 111 and a plurality of 12^{th} island portions 112 arranged along the second direction (e.g., the y direction and/or the −y direction) in a plan view.

The first power supply wiring WLS1 may include a 1-1 power supply wiring WLS11 and a 1-2 power supply wiring WLS12. Also, the second power supply wiring WLS2 may include a 2-1 power supply wiring WLS21 and a 2-2 power supply wiring WLS22.

As shown in FIG. 13B, the 1-1 power supply wiring WLS11 and the 2-1 power supply wiring WLS21 may supply power to a plurality of 11^{th} island portions 111.

The 1-1 power supply wiring WLS11 may supply a 1-1 power supply voltage to a plurality of 11^{th} island portions 111 arranged along the first direction (e.g., the x direction and/or the −x direction) in a plan view. That is, the 1-1 power supply wiring WLS11 may supply the 1-1 power supply voltage to the 1-1 connection wiring WLC11. The 1-1 power supply wiring WLS11 may supply the 1-1 power supply voltage to a plurality of 11^{th} island portions 111 located in positions such as ‘1^{st} column’ and ‘2^{nd} column’. The 11^{th} island portions 111 located in the positions such as ‘1^{st} column’ and ‘2^{nd} column’ may receive the 1-1 power supply voltage from the 1-1 power supply wiring WLS11, and may transmit the 1-1 power supply voltage to a plurality of 1-1 connection wirings WLC11.

The 2-1 power supply wiring WLS21 may supply a 2-1 power supply voltage to a plurality of 11^{th} island portions 111 arranged along the second direction (e.g., the y direction and/or the −y direction) in a plan view. That is, the 2-1 power supply wiring WLS21 may supply the 2-1 power supply voltage to the 2-1 connection wiring WLC21. The 2-1 power supply wiring WLS21 may supply the 2-1 power supply voltage to a plurality of 11^{th} island portions 111 located in positions such as ‘1^{st} row’ and ‘2^{nd} row’. The 11^{th} island portions 111 located in the positions such as ‘1^{st} row’ and ‘2^{nd} row’ may receive the 2-1 power supply voltage from the 2-1 power supply wiring WLS21, and may transmit the 2-1 power supply voltage to a plurality of 2-1 connection wirings WLC21.

As shown in FIG. 13C, the 1-2 power supply wiring WLS12 and the 2-2 power supply wiring WLS22 may supply power to a plurality of 12^{th} island portions 112.

The 1-2 power supply wiring WLS12 may supply a 1-2 power supply voltage to a plurality of 12^{th} island portions 112 arranged along the first direction (e.g., the x direction and/or the −x direction) in a plan view. That is, the 1-2 power supply wiring WLS12 may supply the 1-2 power supply voltage to the 1-2 connection wiring WLC12. The 1-2 power supply wiring WLS12 may supply the 1-2 power supply voltage to a plurality of 12^{th} island portions 112 located in positions such as ‘1^{st} column’ and ‘2^{nd} column’. The 12^{th} island portions 112 located in the positions such as ‘1^{st} column’ and ‘2^{nd} column’ may receive the 1-2 power supply voltage from the 1-2 power supply wiring WLS12, and may transmit the 1-2 power supply voltage to a plurality of 1-2 connection wirings WLC12.

The 2-2 power supply wiring WLS22 may supply a 2-2 power supply voltage to a plurality of 12^{th} island portions 112 arranged along the second direction (e.g., the y direction and/or the −y direction) in a plan view. That is, the 2-2 power supply wiring WLS22 may supply the 2-2 power supply voltage to the 2-2 connection wiring WLC22. The 2-2 power supply wiring WLS22 may supply the 2-2 power supply voltage to a plurality of 12^{th} island portions 112 located in positions such as ‘1^{st} row’ and ‘2^{nd} row’. The 12^{th} island portions 112 located in the positions such as ‘1^{st} row’ and ‘2^{nd} row’ may receive the 2-2 power supply voltage from the 2-2 power supply wiring WLS22, and may transmit the 2-2 power supply voltage to a plurality of 2-2 connection wirings WLC22.

As shown in FIG. 13A, each of the 1-1 power supply wiring WLS11 and the 1-2 power supply wiring WLS12 may be located adjacent to a position of ‘1^{st} column’. Each of the 1-1 power supply wiring WLS11 and the 1-2 power supply wiring WLS12 may be spaced (e.g., spaced apart) from the center of the display area DA along the first direction (e.g., the −x direction). In a plan view, the 1-1 power supply wiring WLS11 and the 1-2 power supply wiring WLS12 may overlap each other.

Each of the 2-1 power supply wiring WLS21 and the 2-2 power supply wiring WLS22 may be located adjacent to a position of ‘1^{st} row’. Each of the 2-1 power supply wiring WLS21 and the 2-2 power supply wiring WLS22 may be spaced (e.g., spaced apart) from the center of the display area DA along the second direction (e.g., the y direction). In a plan view, the 2-1 power supply wiring WLS21 and the 2-2 power supply wiring WLS22 may overlap each other.

The 1-1 power supply voltage and the 1-2 power supply voltage may be the same type of voltage. For example, each of the 1-1 power supply voltage and the 1-2 power supply voltage may be the driving voltage VDD (see FIG. 6A). The 2-1 power supply voltage and the 2-2 power supply voltage may be the same type of voltage. For example, each of the 2-1 power supply voltage and the 2-2 power supply voltage may the common voltage VSS (see FIG. 6A).

A multiplexer may be disposed in the non-display area NDA of the display apparatus 1. For example, the multiplexer may be disposed in the fourth non-display area NDA4 (e.g., see FIG. 3). The multiplexer may be connected to a signal line. For example, when each of the 1-11 connection wiring WLC111 and the 1-21 connection wiring WLC121 is the data line DL (see FIG. 3), the 1-11 connection wiring WLC111 and the 1-21 connection wiring WLC121 may be connected to the same data wiring 110 (see FIG. 3) through the multiplexer.

Because the first connection wiring WLC1 is divided into the 1-1 connection wiring WLC11 and the 1-2 connection wiring WLC12, the 1-1 connection wiring WLC11 may pass through the 12^{th} island portion 112 without being electrically connected to the 12^{th} island portion 112, and the 1-2 connection wiring WLC12 may pass through the 11^{th} island portion 111 without being electrically connected to the 11^{th} island portion 111.

Likewise, because the second connection wiring WLC2 is divided into the 2-1 connection wiring WLC21 and the 2-2 connection wiring WLC22, the 2-1 connection wiring WLC21 may pass through the 12^{th} island portion 112 without being electrically connected to the 12^{th} island portion 112, and the 2-2 connection wiring WLC22 may pass through the 11^{th} island portion 111 without being electrically connected to the 11^{th} island portion 111.

Accordingly, when the display apparatus 1 is stretched, stress applied to the connection wiring WLC may be reduced. Accordingly, the durability of the display apparatus 1 may be improved. Also, an elongation rate of the display apparatus 1 may be increased.

Also, as current flowing through the first connection wiring WLC 1 is distributed to the 1-1 connection wiring WLC11 and the 1-2 connection wiring WLC12, and current flowing through the second connection wiring WLC2 is distributed to the 2-1 connection wiring WLC21 and the 2-2 connection wiring WLC22, heat generation and power consumption in the connection wiring WLC (WLC1, WLC2) may be reduced. Also, a voltage drop occurring in the connection wiring WLC may be reduced.

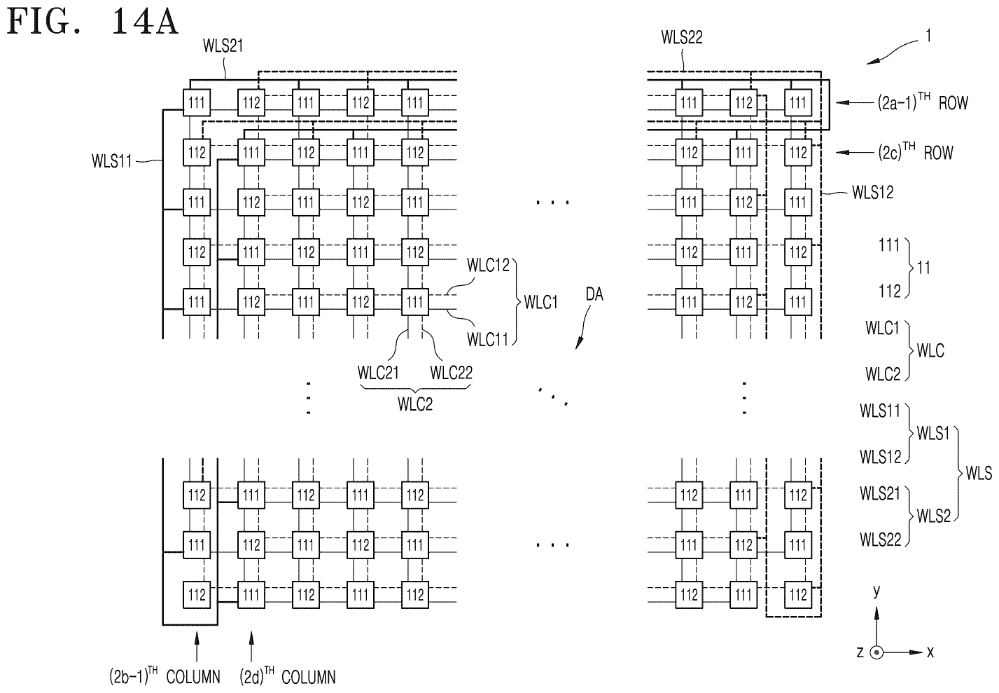

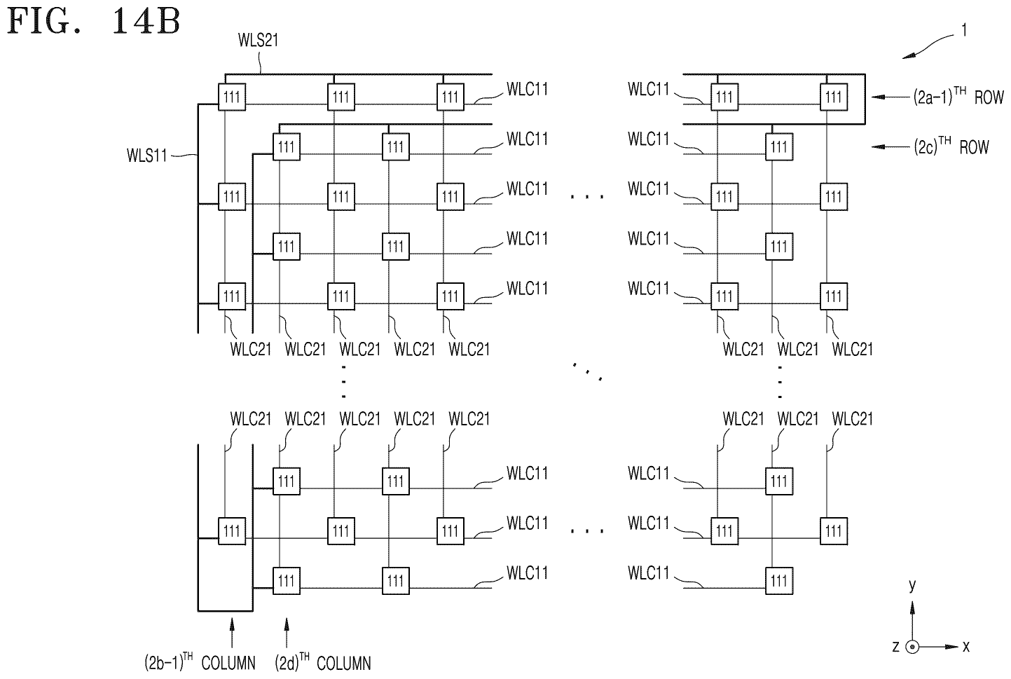

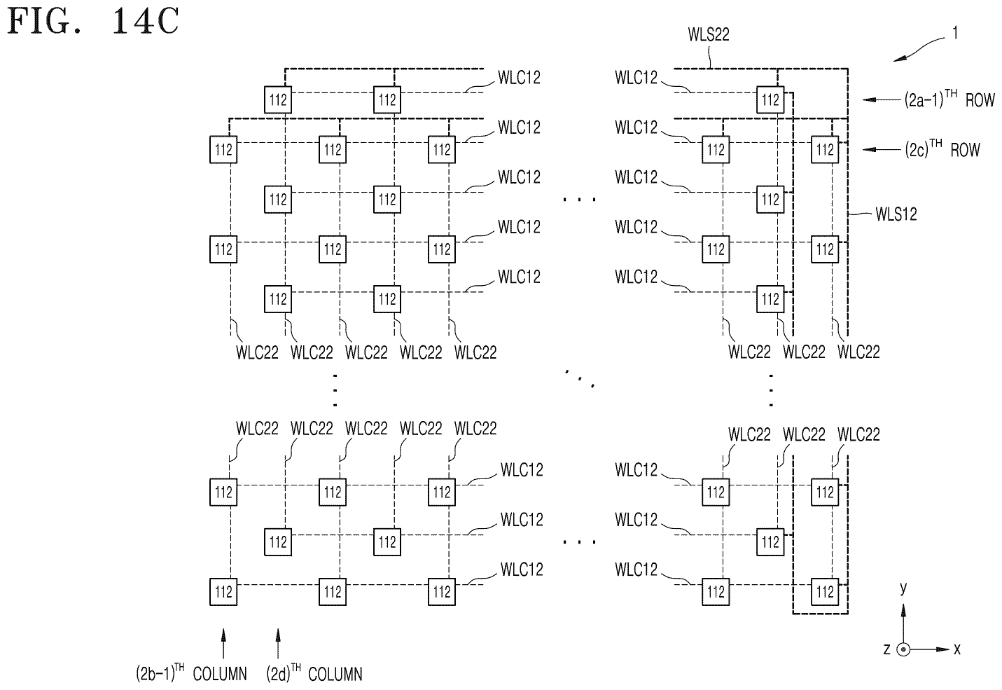

FIGS. 14A-14C are plan views schematically illustrating a part of the display apparatus 1, according to one or more embodiments.

In detail, FIG. 14B is a plan view illustrating only the 11^{th} island portion 111, the 1-1 connection wiring WLC11, and the 2-1 connection wiring WLC21, and FIG. 14C is a plan view illustrating only the 12^{th} island portion 112, the 1-2 connection wiring WLC12, and the 2-2 connection wiring WLC22.

Referring to FIGS. 14A-14C, the first island portion 11 may include the 11^{th} island portion 111 and the 12^{th} island portion 112.

A plurality of 11^{th} island portions 111 and a plurality of 12^{th} island portions 112 may be provided in the display area DA. The plurality of 11^{th} island portions 111 may be spaced (e.g., spaced apart) from each other along the first direction (e.g., the x direction and/or the −x direction) and the second direction (e.g., the y direction and/or the −y direction).

The connection wiring WLC may include the first connection wiring WLC1 and the second connection wiring WLC2. The first connection wiring WLC1 may include the 1-1 connection wiring WLC11 and the 1-2 connection wiring WLC12. Also, the second connection wiring WLC2 may include the 2-1 connection wiring WLC21 and the 2-2 connection wiring WLC22.

As shown in FIG. 14B, the 1-1 connection wiring WLC11 may be electrically connected to a plurality of 11^{th} island portions 111. The 1-1 connection wiring WLC11 may not be electrically connected to the 12^{th} island portion 112. The 2-1 connection wiring WLC21 may be electrically connected to a plurality of 11^{th} island portions 111. The 2-1 connection wiring WLC21 may not be electrically connected to the 12^{th} island portion 112.

As shown in FIG. 14C, the 1-2 connection wiring WLC12 may be electrically connected to a plurality of 12^{th} island portions 112. The 1-2 connection wiring WLC12 may not be electrically connected to the 11^{th} island portion 111. The 2-2 connection wiring WLC22 may be electrically connected to a plurality of 12^{th} island portions 112. The 2-2 connection wiring WLC22 may not be electrically connected to the 11^{th} island portion 111.

The power supply wiring WLS may supply power to the first island portion 11. The power supply wiring WLS may include the first power supply wiring WLS1 and the second power supply wiring WLS2. The first power supply wiring WLS1 may supply a first power supply voltage to a plurality of 11^{th} island portions 111 and a plurality of 12^{th} island portions 112 arranged along the first direction (e.g., the x direction and/or the −x direction) in a plan view. The second power supply wiring WLS2 may supply a second power supply voltage to a plurality of 11^{th} island portions 111 and a plurality of 12^{th} island portions 112 arranged along the second direction (e.g., the y direction and/or the −y direction) in a plan view.

The first power supply wiring WLS1 may include the 1-1 power supply wiring WLS11 and the 1-2 power supply wiring WLS12. Also, the second power supply wiring WLS2 may include the 2-1 power supply wiring WLS21 and the 2-2 power supply wiring WLS22.

As shown in FIG. 14B, the 1-1 power supply wiring WLS11 and the 2-1 power supply wiring WLS21 may supply power to a plurality of 11^{th} island portions 111.

The 1-1 power supply wiring WLS11 may supply a 1-1 power supply voltage to a plurality of 11^{th} island portions 111 arranged along the first direction (e.g., the x direction and/or the −x direction) in a plan view. That is, the 1-1 power supply wiring WLS11 may supply the 1-1 power supply voltage to the 1-1 connection wiring WLC11. The 1-1 power supply wiring WLS11 may supply the 1-1 power supply voltage to a plurality of 11^{th} island portions 111 located in positions such as ‘1^{st} column’ and ‘2^{nd} column’. The 11^{th} island portions located in the positions such as ‘1^{st} column’ and ‘2^{nd} column’ may receive the 1-1 power supply voltage from the 1-1 power supply wiring WLS11, and may transmit the 1-1 power supply voltage to a plurality of 1-1 connection wirings WLC11.

The 2-1 power supply wiring WLS21 may supply a 2-1 power supply voltage to a plurality of 11^{th} island portions 111 arranged along the second direction (e.g., the y direction and/or the −y direction) in a plan view. That is, the 2-1 power supply wiring WLS21 may supply the 2-1 power supply voltage to the 2-1 connection wiring WLC21. The 2-1 power supply wiring WLS21 may supply the 2-1 power supply voltage to a plurality of 11^{th} island portions 111 located in positions such as ‘1^{st} row’ and ‘2^{nd} row’. The 11^{th} island portions 111 located in the positions such as ‘1^{st} row’ and ‘2^{nd} row’ may receive the 2-1 power supply voltage from the 2-1 power supply wiring WLS21, and may transmit the 2-1 power supply voltage to a plurality of 2-1 connection wirings WLC21.

As shown in FIG. 14C, the 1-2 power supply wiring WLS12 and the 2-2power supply wiring WLS22 may supply power to a plurality of 12^{th} island portions 112.

The 1-2 power supply wiring WLS12 may supply a 1-2 power supply voltage to a plurality of 12^{th} island portions 112 arranged along the first direction (e.g., the x direction and/or the −x direction) in a plan view. That is, the 1-2 power supply wiring WLS12 may supply the 1-2 power supply voltage to the 1-2 connection wiring WLC12. The 1-2 power supply wiring WLS12 may supply the 1-2 power supply voltage to a plurality of 12^{th} island portions 112 located in positions such as ‘last column’ and ‘second to last column’. The 12^{th} island portions 112 located in the positions such as ‘last column’ and ‘second to last column’ may receive the 1-2 power supply voltage from the 1-2 power supply wiring WLS12, and may transmit the 1-2 power supply voltage to a plurality of 1-2 connection wirings WLC12.

The 2-2 power supply wiring WLS22 may supply a 2-2 power supply voltage to a plurality of 12^{th} island portions 112 arranged along the second direction (e.g., the y direction and/or the −y direction) in a plan view. That is, the 2-2 power supply wiring WLS22 may supply the 2-2 power supply voltage to the 2-2 connection wiring WLC22. The 2-2 power supply wiring WLS22 may supply the 2-2 power supply voltage to a plurality of 12^{th} island portions 112 located in positions such as ‘1^{st} row’ and ‘2^{nd} row’.

The 12^{th} island portions 112 located in the positions such as ‘1^{st} row’ and ‘2^{nd} row’ may receive the 2-2 power supply voltage from the 2-2 power supply wiring WLS22, and may transmit the 2-2 power supply voltage to a plurality of 2-2 connection wirings WLC22.

As shown in FIG. 14A, the 1-1 power supply wiring WLS11 may be located adjacent to a position of ‘1^{st} column’. Also, the 1-2 power supply wiring WLS12 may be located adjacent to a position of ‘last column’. The 1-1 power supply wiring WLS11 and the 1-2 power supply wiring WLS12 may be located at opposite positions with respect to the center of the display area DA. The 1-1 power supply wiring WLS11 and the 1-2 power supply wiring WLS12 may be spaced (e.g., spaced apart) from each other with the center of the display area DA therebetween. In a plan view, the 1-1 power supply wiring WLS11 may not overlap the 1-2 power supply wiring WLS12.

Each of the 2-1 power supply wiring WLS21 and the 2-2 power supply wiring WLS22 may be located adjacent to a position of ‘1^{st} row’. Each of the 2-1 power supply wiring WLS21 and the 2-2 power supply wiring WLS22 may be spaced (e.g., spaced apart) from the center of the display area DA along the second direction (e.g., the y direction). In a plan view, the 2-1 power supply wiring WLS21 may overlap the 2-2 power supply wiring WLS22.

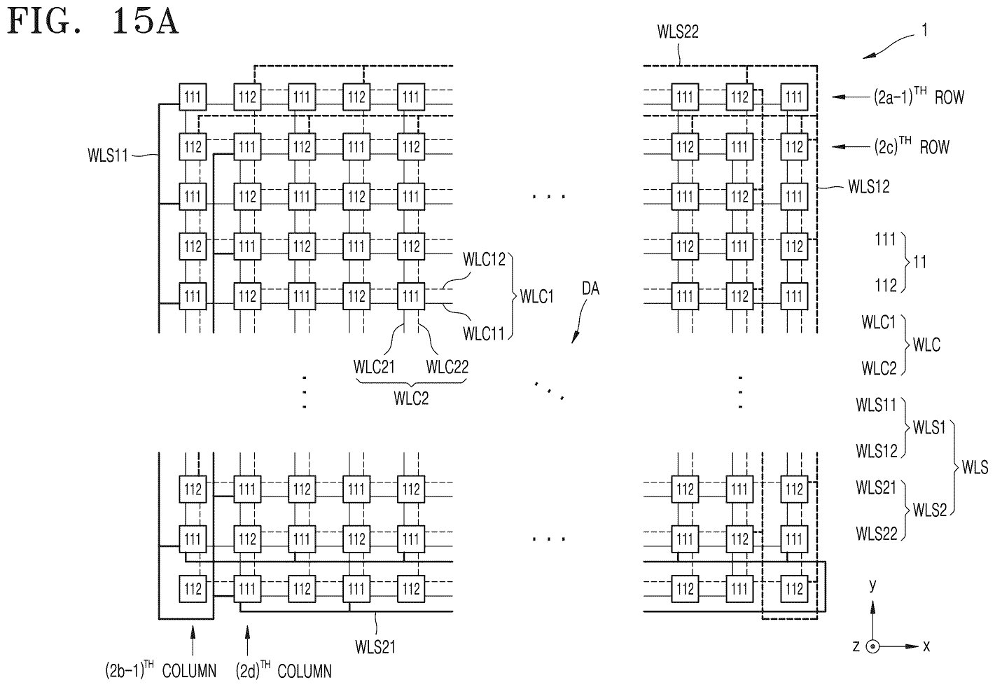

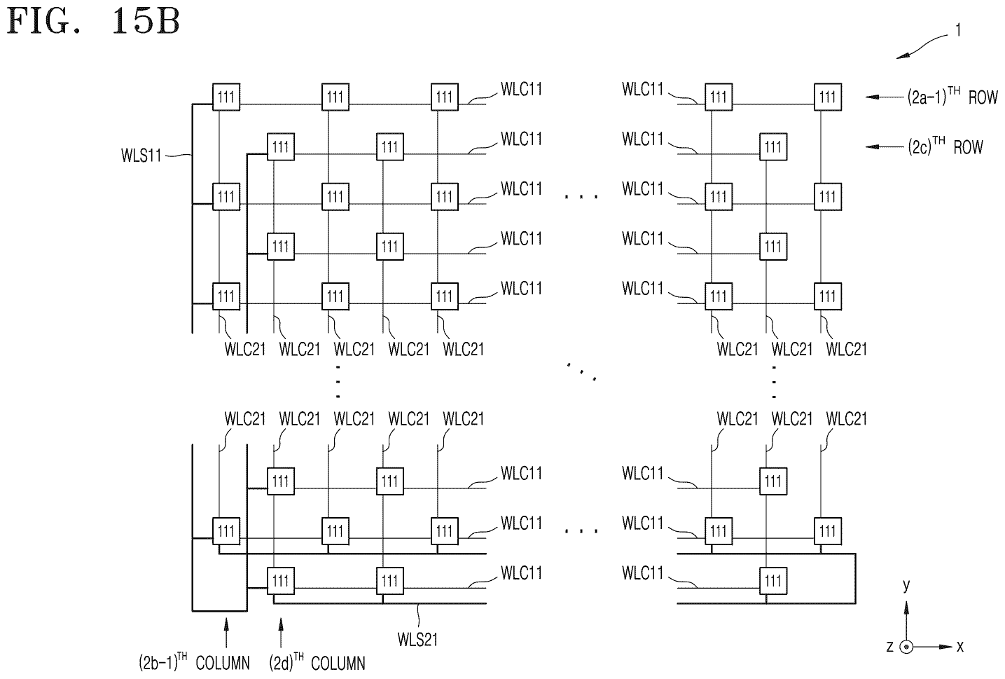

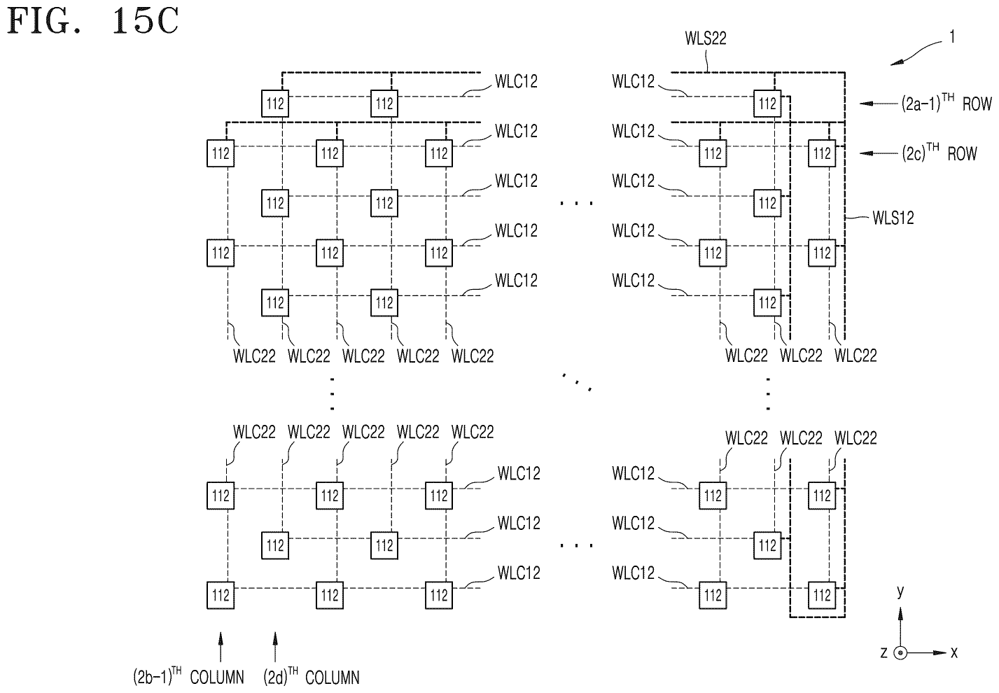

FIGS. 15A-15C are plan views schematically illustrating a part of the display apparatus 1, according to one or more embodiments.

In detail, FIG. 15B is a plan view illustrating only the 11^{th} island portion 111, the 1-1 connection wiring WLC11 and the 2-1 connection wiring WLC21. FIG. 15C is a plan view illustrating only the 12^{th} island portion 112, the 1-2 connection wiring WLC12, and the 2-2 connection wiring WLC22.

Referring to FIGS. 15A-15C, the first island portion 11 may include the 11^{th} island portion 111 and the 12^{th} island portion 112.

A plurality of 11^{th} island portions 111 and a plurality of 12^{th} island portions 112 may be provided in the display area DA. The plurality of 11^{th} island portions 111 may be spaced (e.g., spaced apart) from each other along the first direction (e.g., the x direction and/or the −x direction) and the second direction (e.g., the y direction and/or the −y direction).

The connection wiring WLC may include the first connection wiring WLC1 and the second connection wiring WLC2. The first connection wiring WLC1 may include the 1-1 connection wiring WLC11 and the 1-2 connection wiring WLC12. Also, the second connection wiring WLC2 may include the 2-1 connection wiring WLC21 and the 2-2 connection wiring WLC22.

As shown in FIG. 15B, the 1-1 connection wiring WLC11 may be electrically connected to a plurality of 11^{th} island portions 111. The 1-1 connection wiring WLC11 may not be electrically connected to the 12^{th} island portion 112. The 2-1 connection wiring WLC21 may be electrically connected to a plurality of 11^{th} island portions 111. The 2-1 connection wiring WLC21 may not be electrically connected to the 12^{th} island portion 112.

As shown in FIG. 15C, the 1-2 connection wiring WLC12 may be electrically connected to a plurality of 12^{th} island portions 112. The 1-2 connection wiring WLC12 may not be electrically connected to the 11^{th} island portion 111. The 2-2 connection wiring WLC22 may be electrically connected to a plurality of 12^{th} island portions 112. The 2-2 connection wiring WLC22 may not be electrically connected to the 11^{th} island portion 111.

The power supply wiring WLS may supply power to the first island portion 11. The power supply wiring WLS may include the first power supply wiring WLS1 and the second power supply wiring WLS2. The first power supply wiring WLS1 may supply a first power supply voltage to a plurality of 11^{th} island portions 111 and a plurality of 12^{th} island portions 112 arranged along the first direction (e.g., the x direction and/or the −x direction) in a plan view. The second power supply wiring WLS2 may supply a second power supply voltage to a plurality of 11^{th} island portions 111 and a plurality of 12^{th} island portions 112 arranged along the second direction (e.g., the y direction and/or the −y direction) in a plan view.

The first power supply wiring WLS1 may include the 1-1 power supply wiring WLS11 and the 1-2 power supply wiring WLS12. Also, the second power supply wiring WLS2 may include the 2-1 power supply wiring WLS21 and the 2-2 power supply wiring WLS22.

As shown in FIG. 15B, the 1-1 power supply wiring WLS11 and the 2-1 power supply wiring WLS21 may supply power to a plurality of 11^{th} island portions 111.

The 1-1 power supply wiring WLS11 may supply a 1-1 power supply voltage to a plurality of 11^{th} island portions 111 arranged along the first direction (e.g., the x direction and/or the −x direction) in a plan view. That is, the 1-1 power supply wiring WLS11 may supply the 1-1 power supply voltage to the 1-1 connection wiring WLC11. The 1-1 power supply wiring WLS11 may supply the 1-1 power supply voltage to a plurality of 11^{th} island portions 111 located in positions such as ‘1^{st} column’ and ‘2^{nd} column’. The 11^{th} island portions 111 located in the positions such as ‘1^{st} column’ and ‘2^{nd} column’ may receive the 1-1 power supply voltage from the 1-1 power supply wiring WLS11, and may transmit the 1-1 power supply voltage to a plurality of 1-1 connection wirings WLC11.

The 2-1 power supply wiring WLS21 may supply a 2-1 power supply voltage to a plurality of 11^{th} island portions 111 arranged along the second direction (e.g., the y direction and/or the −y direction) in a plan view. That is, the 2-1 power supply wiring WLS21 may supply the 2-1 power supply voltage to the 2-1 connection wiring WLC21. The 2-1 power supply wiring WLS21 may supply the 2-1 power supply voltage to a plurality of 11^{th} island portions 111 located in positions such as ‘last row’ and ‘second to last row’. The 11^{th} island portions 111 located in the positions such as ‘last row’ and ‘second to last row’ may receive the 2-1 power supply voltage from the 2-1 power supply wiring WLS21, and may transmit the 2-1 power supply voltage to a plurality of 2-1 connection wirings WLC21.

As shown in FIG. 15C, the 1-2 power supply wiring WLS12 and the 2-2 power supply wiring WLS22 may supply power to a plurality of 12^{th} island portions 112.

The 1-2 power supply wiring WLS12 may supply a 1-2 power supply voltage to a plurality of 12^{th} island portions 112 arranged along the first direction (e.g., the x direction and/or the −x direction) in a plan view. That is, the 1-2 power supply wiring WLS12 may supply the 1-2 power supply voltage to the 1-2 connection wiring WLC12. The 1-2 power supply wiring WLS12 may supply the 1-2 power supply voltage to a plurality of 12^{th} island portions 112 located in positions such as ‘last column’ and ‘second to last column’. The 12^{th} island portions 112 located in the positions such as ‘last column’ and ‘second to last column’ may receive the 1-2 power supply voltage from the 1-2 power supply wiring WLS12, and may transmit the 1-2 power supply voltage to a plurality of 1-2 connection wirings WLC12.

The 2-2 power supply wiring WLS22 may supply a 2-2 power supply voltage to a plurality of 12^{th} island portions 112 arranged along the second direction (e.g., the y direction and/or the −y direction) in a plan view. That is, the 2-2 power supply wiring WLS22 may supply the 2-2 power supply voltage to the 2-2 connection wiring WLC22. The 2-2 power supply wiring WLS22 may supply the 2-2 power supply voltage to a plurality of 12^{th} island portions 112 located in positions such as ‘1^{st} row’ and ‘2^{nd} row’.

The 12^{th} island portions 112 located in the positions such as ‘1^{st} row’ and ‘2^{nd} row’ may receive the 2-2 power supply voltage from the 2-2 power supply wiring WLS22, and may transmit the 2-2 power supply voltage to a plurality of 2-2 connection wirings WLC22.

As shown in FIG. 15A, the 1-1 power supply wiring WLS11 may be located adjacent to a position of ‘1^{st} column’. Also, the 1-2 power supply wiring WLS12 may be located adjacent to a position of ‘last column’. The 1-1 power supply wiring WLS11 and the 1-2 power supply wiring WLS12 may be located at opposite positions with respect to the center of the display area DA. The 1-1 power supply wiring WLS11 and the 1-2 power supply wiring WLS12 may be spaced (e.g., spaced apart) from each other with the center of the display area DA therebetween. In a plan view, the 1-1 power supply wiring WLS11 and the 1-2 power supply wiring WLS12 may not overlap each other.

The 2-1 power supply wiring WLS21 may be located adjacent to a position of ‘last row’. Also, the 2-2 power supply wiring WLS22 may be located adjacent to a position of ‘1^{st} row’. The 2-1 power supply wiring WLS21 and the 2-2 power supply wiring WLS22 may be located at opposite positions with respect to the center of the display area DA. The 2-1 power supply wiring WLS21 and the 2-2 power supply wiring WLS22 may be spaced (e.g., spaced apart) from each other with the center of the display area DA therebetween. The 2-1 power supply wiring WLS21 and the 2-2 power supply wiring WLS22 may not overlap each other.

In this structure, the 1-1 power supply wiring WLS11, the 2-1 power supply wiring WLS21, the 1-2 power supply wiring WLS12, and the 2-2 power supply wiring WLS22 may be disposed to be around (e.g., to surround) the display area DA.

The display apparatus 1 according to the above embodiments may be used in various electronic devices capable of providing an image. The term “electronic device” refers to a device capable of providing a certain image by using electricity.

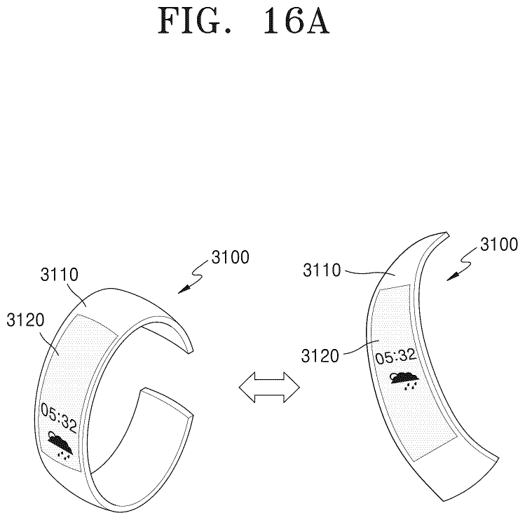

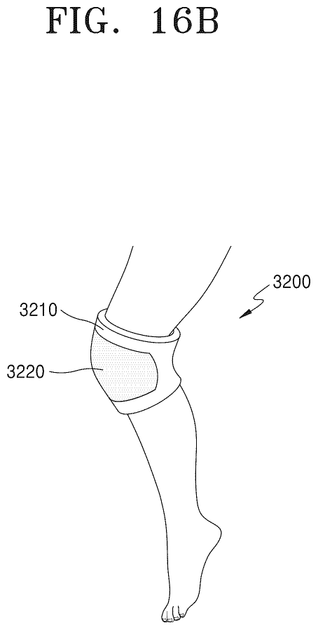

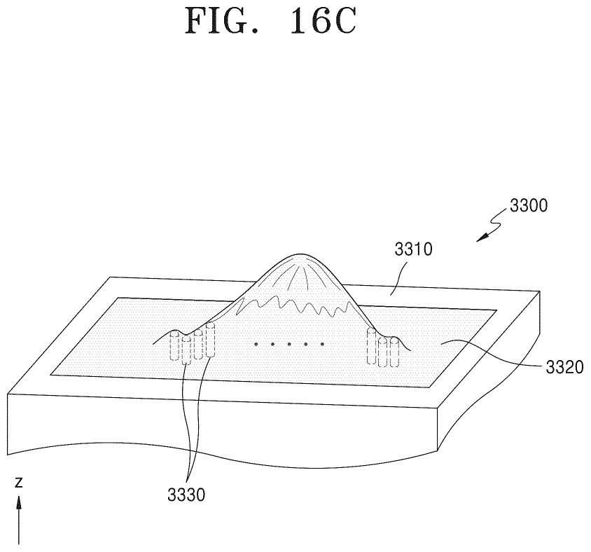

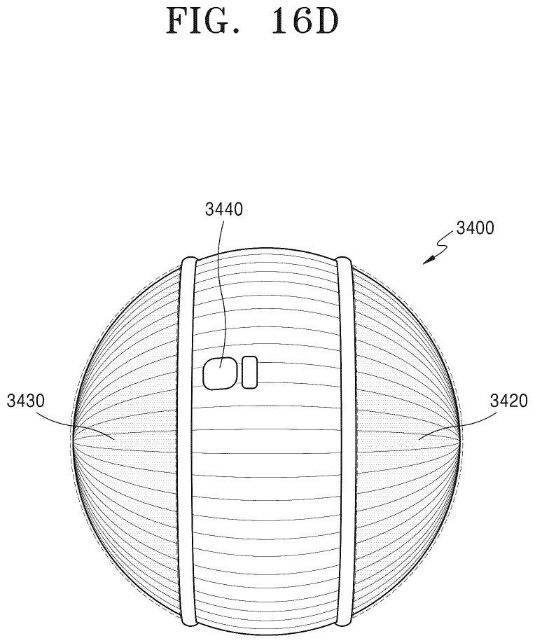

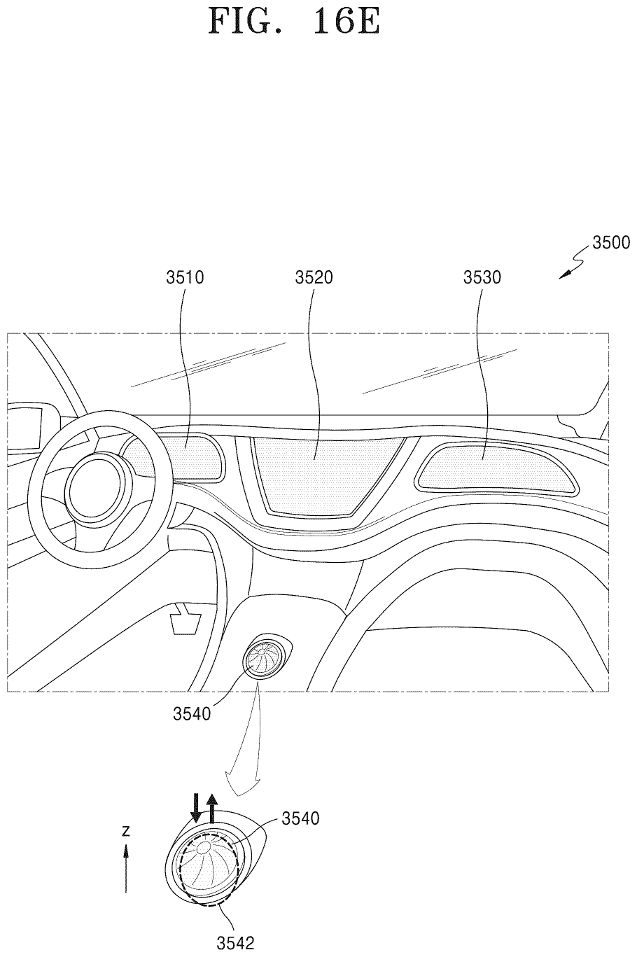

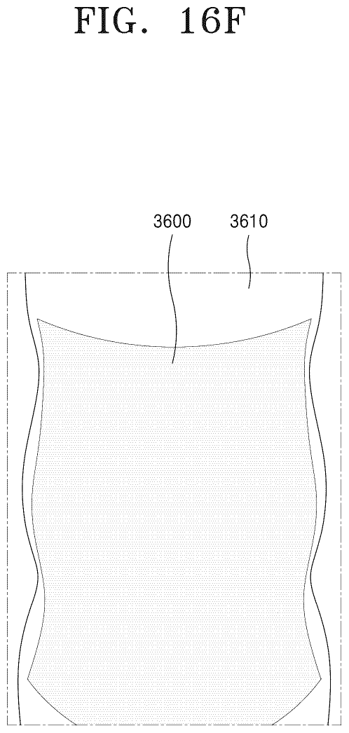

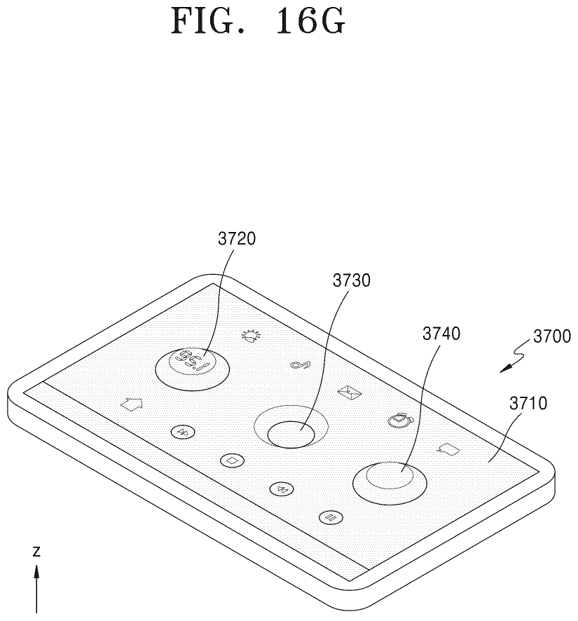

FIGS. 16A-16G are perspective views schematically illustrating embodiments of an electronic device including a display apparatus, according to one or more embodiments.

Referring to FIG. 16A, a display apparatus according to one or more embodiments may be used in a wearable electronic device 3100 that may be worn on a user's body part. The wearable electronic device 3100 may include a body portion 3110 and a display unit 3120 provided on the body portion 3110. A display apparatus according to one or more embodiments may be used as the display unit 3120 of the wearable electronic device 3100. As shown in FIG. 16A, the wearable electronic device 3100 may be deformable. In one or more embodiments, the wearable electronic device 3100 may be used as a smart watch or a smartphone according to a user's selection.

FIG. 16B illustrates a medical electronic device 3200. In one or more embodiments, the medical electronic device 3200 may include a body portion 3210 and a light-emitting unit 3220. A display apparatus according to one or more embodiments may be used as the light-emitting unit 3220 of the medical electronic device 3200. The light-emitting unit 3220 may emit light of a certain wavelength band (e.g., infrared light or visible light) to a patient's body. In one or more embodiments, the body portion 3210 may include a stretchable fiber material, and may have a structure that may be worn on a user's body.

FIG. 16C illustrates an educational electronic device 3300. In one or more embodiments, the educational electronic device may include a display unit 3320 provided in a frame 3310. The display unit 3320 may use a display apparatus according to one or more embodiments. An image such as a sea with waves, a snow-covered mountain, or a volcano through which lava flows may be provided through the display unit 3320, and in this case, the display unit 3320 may be stretched in a height direction (e.g., the z direction) by reflecting the height of the waves, mountain, and/or volcano. In one or more embodiments, a part of the display unit 3320 may be sequentially changed in height along a direction in which the lava flows to three-dimensionally show the movement of the lava. The educational electronic device 3300 may include a plurality of pins (or stroke units 3330) disposed on a rear surface of the display unit 3320 so that the display unit 3320 is stretched in the height direction (e.g., z direction). As the pins 3330 move along the third direction (e.g., the z direction or the −z direction), an image displayed on the display unit 3320 may be implemented to have a three-dimensional height. Although the educational electronic device 3300 is described with reference to FIG. 16C, its use is not limited as long as certain image information is provided.

Although an electronic device as shown in FIGS. 16A-16C is an electronic device whose shape is variable, the present disclosure is not limited thereto. As in embodiments described below, a display apparatus according to one or more embodiments may be used in an electronic device in which a portion for displaying an image (e.g., a screen) is fixed.

FIG. 16D illustrates a robot 3400 as an electronic device, according to one or more embodiments. The robot 3400 may recognize movement or an object by using a camera unit 3440, and may display a certain image to a user through display units 3420 and 3430. In one or more embodiments, because display apparatuses according to one or more embodiments may be stretched in various directions as described above, the display apparatuses may be assembled into a body frame having a hemispherical shape, and thus, the robot 3400 may include the display units 3420 and 3430 each having a hemispherical shape.

FIG. 16E illustrates a display device 3500 for a vehicle as an electronic device, according to one or more embodiments. The display device 3500 for a vehicle may include a cluster 3510, a center information display (CID) 3520, and/or a passenger display (co-driver display) 3530. Because a display apparatus according to one or more embodiments may be stretched in various directions, the display apparatus may be used in the cluster 3510, the CID 3520, and/or the co-driver display 3530 regardless of a shape of an internal frame of a vehicle.

Although the cluster 3510, the CID 3520, and/or the co-driver display 3530 are separated from each other in FIG. 16E, the present disclosure is not limited thereto. In another embodiment, two or more selected from the cluster 3510, the CID 3520, and the co-driver display 3530 may be integrally connected.

In one or more embodiments, the display device 3500 for a vehicle may include a button 3540 for displaying a certain image. Referring to an enlarged view of FIG. 16E, the button 3540 having a hemispherical shape may include an object 3542 that provides a feeling of using the button while moving in the z direction or the −z direction, and a display apparatus disposed on the object 3542. In one or more embodiments, when the object 3542 has a three-dimensionally rounded surface, the display apparatus may also have a three-dimensionally rounded surface.

FIG. 16F illustrates an electronic device 3600 for advertisement or exhibition as an electronic device, according to one or more embodiments. In one or more embodiments, the electronic device 3600 for advertisement or exhibition may be installed on a fixed structure 3610 such as a wall or a pillar. When the structure 3610 includes an uneven surface as shown in FIG. 16F, the electronic device 3600 for advertisement or exhibition may be disposed along the uneven surface of the structure 3610. In one or more embodiments, the electronic device 3600 for advertisement or exhibition may be installed on the structure 3610 by using a heat shrink film and/or the like.

FIG. 16G illustrates a controller 3700 as an electronic device, according to one or more embodiments. The controller 3700 may include an image-type button. For example, a display unit 3710 of the controller 3700 may include first to third button areas 3720, 3730, and 3740 protruding in the z direction or protruding in the −z direction (or recessed in the z direction). In one or more embodiments, the first and third button areas 3720 and 3740 may protrude in the z direction, and the second button area 3730 may protrude in the −z direction (or be recessed in the z direction).

While the present disclosure has been particularly shown and described with reference to embodiments thereof, it will be understood by one of ordinary skill in the art that various modifications and equivalent other embodiments may be made from the present disclosure. Accordingly, the true technical scope of the present disclosure may be defined by the technical spirit and scope of the appended claims and their equivalents.

According to one or more embodiments, an elongation rate of a display apparatus may be increased and the durability of the display apparatus may be improved.

These effects, aspects, and features are shown as examples, and do not limit the scope of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims and their equivalents.

What is claimed is:

1. A display apparatus having a display area and a non-display area, the display apparatus comprising:
a plurality of 11^{th} island portions and a plurality of 12^{th} island portions in the display area and alternately arranged to be spaced from each other along a first direction and a second direction intersecting the first direction; and
a first connection wiring extending in the first direction overlapping the plurality of 11^{th} island portions and the plurality of 12^{th} island portions arranged along the first direction in a plan view,
wherein the first connection wiring comprises:
a 1-1 connection wiring electrically connected to each of the plurality of 11^{th} island portions; and
a 1-2 connection wiring spaced from the 1-1 connection wiring and electrically connected to each of the plurality of 12^{th} island portions.

2. The display apparatus of claim 1, wherein, in a cross-sectional view,
the 1-1 connection wiring is spaced from a transistor of a 12^{th} island portion from among the plurality of 12^{th} island portions, and
the 1-2 connection wiring is spaced from a transistor of a 11^{th} island portion from among the plurality of 11^{th} island portions.

3. The display apparatus of claim 1, wherein the 1-1 connection wiring comprises a 1-11 connection wiring, and a 1-12 connection wiring on a different layer from the 1-11 connection wiring.

4. The display apparatus of claim 3, wherein each of the 1-11 connection wiring and the 1-12 connection wiring has a curved or bent shape,
wherein, in a plan view, the 1-11 connection wiring and the 1-12 connection wiring cross each other at a first position and are spaced from each other at a second position different from the first position.

5. The display apparatus of claim 1, further comprising a second connection wiring extending in the second direction overlapping the plurality of 11^{th} island portions and the plurality of 12^{th} island portions arranged along the second direction in a plan view,
wherein the second connection wiring comprises:
a 2-1 connection wiring electrically connected to each of the plurality of 11^{th} island portions; and
a 2-2 connection wiring spaced from the 1-1 connection wiring and electrically connected to each of the plurality of 12^{th} island portions.

6. The display apparatus of claim 5, further comprising a plurality of first connection wirings and a plurality of second connection wirings,
wherein the plurality of first connection wirings are spaced from each other along the second direction, and
the plurality of second connection wirings are spaced from each other along the first direction.

7. The display apparatus of claim 5, wherein at least one of the first connection wiring or the second connection wiring comprises at least one of a voltage line or a signal line.

8. The display apparatus of claim 5, further comprising:
a first power supply wiring comprising a 1-1 power supply wiring configured to supply a 1-1 power supply voltage to the 1-1 connection wiring and a 1-2 power supply wiring configured to supply a 1-2 power supply voltage to the 1-2 connection wiring; and
a second power supply wiring comprising a 2-1 power supply wiring configured to supply a 2-1 power supply voltage to the 2-1 connection wiring and a 2-2 power supply wiring configured to supply a 2-2 power supply voltage to the 2-2 connection wiring.

9. The display apparatus of claim 8, wherein, in a plan view,
the 1-1 power supply wiring overlaps the 1-2 power supply wiring, and
the 2-1 power supply wiring overlaps the 2-2 power supply wiring.

10. The display apparatus of claim 8, wherein the 1-1 power supply wiring, the 2-1 power supply wiring, the 1-2 power supply wiring, and the 2-2 power supply wiring are around the display area.

11. An electronic device comprising a display apparatus having a display area and a non-display area, the display apparatus comprising:
a plurality of 11^{th} island portions spaced from each other along a first direction and a second direction intersecting the first direction;
a plurality of 12^{th} island portions spaced from each other along the first direction and the second direction; and
a first connection wiring extending in the first direction overlapping the plurality of 11^{th} island portions and the plurality of 12^{th} island portions arranged along the first direction in a plan view,
wherein the first connection wiring comprises:
a 1-1 connection wiring electrically connected to each of the plurality of 11^{th} island portions; and
a 1-2 connection wiring spaced from the 1-1 connection wiring and electrically connected to each of the plurality of 12^{th} island portions.

12. The electronic device of claim 11, wherein the plurality of 11^{th} island portions and the plurality of 12^{th} island portions are arranged in a lattice shape.

13. The electronic device of claim 12, wherein the plurality of 11^{th} island portions are located at a position of (2a-1)^{th} row, (2b-1)^{th} column or a position of (2c)^{th} row, (2d)^{th} column, (where a, b, c, and d are positive numbers greater than 0).

14. The electronic device of claim 12, wherein the plurality of 12^{th} island portions are located at a position of (2a-1)^{th} row, (2d)^{th} column or a position of (2c)^{th} row, (2b-1)^{th} column (where a, b, c, and d are positive numbers greater than 0).

15. The electronic device of claim 11, wherein, in a cross-sectional view,
the 1-1 connection wiring is spaced from a transistor of a 12^{th} island portion from among the plurality of 12^{th} island portions, and
the 1-2 connection wiring is spaced from a transistor of a 11^{th} island portion from among the plurality of 11^{th} island portions.

16. The electronic device of claim 11, wherein the 1-1 connection wiring comprises a 1-11 connection wiring, and a 1-12 connection wiring on a different layer from the 1-11 connection wiring.

17. The electronic device of claim 16, wherein each of the 1-11 connection wiring and the 1-12 connection wiring has a curved or bent shape,
wherein, in a plan view, the 1-11 connection wiring and the 1-12 connection wiring cross each other at a first position and are spaced from each other at a second position different from the first position.

18. The electronic device of claim 11, wherein the display apparatus further comprises a second connection wiring extending in the second direction overlapping the plurality of 11^{th} island portions and the plurality of 12^{th} island portions arranged along the second direction in a plan view,
wherein the second connection wiring comprises:
a 2-1 connection wiring electrically connected to each of the plurality of 11^{th} island portions; and
a 2-2 connection wiring spaced from the 1-1 connection wiring and electrically connected to each of the plurality of 12^{th} island portions.

19. The electronic device of claim 18, wherein the display apparatus further comprises:
a first power supply wiring comprising a 1-1 power supply wiring configured to supply a 1-1 power supply voltage to the 1-1 connection wiring and a 1-2 power supply wiring configured to supply a 1-2 power supply voltage to the 1-2 connection wiring; and
a second power supply wiring comprising a 2-1 power supply wiring configured to supply a 2-1 power supply voltage to the 2-1 connection wiring and a 2-2 power supply wiring configured to supply a 2-2 power supply voltage to the 2-2 connection wiring.

20. The electronic device of claim 19, wherein, in a plan view,
the 1-1 power supply wiring overlaps the 1-2 power supply wiring, and
the 2-1 power supply wiring overlaps the 2-2 power supply wiring.
